(19) United States
(12) Patent Application Publication
(10) Pub. No.: US 2026/0344031 A1
(43) Pub. Date: Oct. 29, 2026

(54) SEMICONDUCTOR DEVICE AND METHOD FOR FORMING THE SAME

(71) Applicant: Taiwan Semiconductor Manufacturing Company, Ltd., Hsinchu (TW)

(72) Inventor: Jhon-Jhy LIAW, Zhudong Township (TW)

(21) Appl. No.: 19/186,936

(22) Filed: Apr. 23, 2025

(51) Int. Cl. H10D 84/85; H03K 19/0948; H10D 30/00; H10D 30/01; H10D 30/43; H10D 62/10

(52) U.S. Cl. CPC H10D 84/851; H10D 30/014; H10D 30/0191; H10D 30/43; H10D 30/502; H10D 62/102; H10D 62/115; H10D 62/121; H10D 84/856; H03K 19/0948

(57) ABSTRACT

A semiconductor device includes first, second, third, and fourth active regions, and includes fifth, sixth, seventh, and eighth active regions that are spaced apart from the first, second, third, and fourth active regions in the second direction. The semiconductor device further includes isolation structures, disposed between a sixth base fin of the sixth active region and a seventh base fin of the seventh active region, and between the seventh base fin and an eighth base fin of the eighth active region. The semiconductor device further includes a first top dielectric layer formed on the isolation structures and between the sixth seventh base fins, and a second top dielectric layer formed on the isolation structures and between the seventh and eighth base fins. The first thickness of the first top dielectric layer is greater than the second thickness of the second top dielectric layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling down generally provides benefits by increasing production efficiency and lowering associated costs. Such scaling down has also increased the complexity of processing and manufacturing ICs and, for these advancements to be realized, similar developments in IC processing and manufacturing are needed.

As IC technologies progress towards smaller technology nodes, multi-gate metal-oxide-semiconductor field effect transistors (multi-gate MOSFETs, or multi-gate devices) have been introduced to improve gate control by increasing gate-channel coupling, reducing off-state current, and reducing short-channel effects. A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. While existing GAA transistors may be generally adequate for their intended purposes, they are not entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, and 1E illustrate circuit schematics of various STD cells in the array of circuit cells in the logic region of the IC chip, in accordance with some embodiments of the present disclosure.

FIG. 2 illustrates a perspective view of an embodiment of a GAA transistor in the array of circuit cells, in accordance with some embodiments of the present disclosure.

FIG. 3 illustrates a top view (or a layout) of a semiconductor device of an array of the circuit cells in the logic region of the IC chip, in accordance with some embodiments of the present disclosure.

FIGS. 4A and 4B illustrate Y-Z cross-sectional views of the semiconductor device along lines A-A′ and B-B′ of FIG. 3, respectively, in accordance with some embodiments of the present disclosure.

FIGS. 4C and 4D illustrate X-Z cross-sectional views of the semiconductor device along lines C-C′ and D-D′ of FIG. 3, respectively, in accordance with some embodiments of the present disclosure.

FIG. 5 illustrates an X-Z cross-sectional view of the semiconductor device along a line D-D′ of FIG. 3, in accordance with some alternative embodiments of the present disclosure.

FIGS. 6A and 6B illustrate partial enlarged cross-sectional views of the Y-Z cross-sectional views of FIGS. 4A and 4B, in accordance with some embodiments of the present disclosure.

FIGS. 7, 8A and 8B illustrate perspective views of a workpiece at various fabrication stages for the semiconductor device, in accordance with some embodiments of the present disclosure.

FIGS. 9A, 10A, 11A, 12A, 13A, and 14A illustrate Y-Z cross-sectional views of the workpiece at various fabrication stages along line A-A′ of FIGS. 8A and 8B, in accordance with some embodiments of the present disclosure.

FIGS. 9B, 10B, 11B, 12B, 13B, and 14B illustrate Y-Z cross-sectional views of the workpiece at various fabrication stages along line B-B′ of FIGS. 8A and 8B, in accordance with some embodiments of the present disclosure.

FIGS. 10C, 11C, 12C, 13C, and 14C illustrate X-Z cross-sectional views of the workpiece at various fabrication stages along line C-C′ of FIGS. 8A and 8B, in accordance with some embodiments of the present disclosure.

FIGS. 10D, 11D, 12D, 13D, and 14D illustrate X-Z cross-sectional views of the workpiece at various fabrication stages along line D-D′ of FIGS. 8A and 8B, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to semiconductor devices with field-effect transistors (FETs), such as three-dimensional gate-all-around (GAA) transistors. Generally, a GAA transistor may include a plurality of vertically stacked nanostructures (e.g., nanosheets, nanowires, or nanorods) in a channel region of the transistor, thereby allowing better gate control, lowered leakage current, and improved scaling capability for various IC applications.

The GAA transistor structures described below may be patterned by any suitable method. For example, the structures may be patterned by using one or more photolithography processes, including double-patterning or multi-patterning processes. In general, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structures.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures that include active regions (including base fins), isolation structures formed between the active regions, and top dielectric layers formed over the isolation structures. The top dielectric layers may protect the isolation structures during channel release process, so as to prevent the sidewalls of base fins from being exposed during the channel release process. In this way, the contact area between the base fins and gate structures to be formed afterwards will be reduced, so that the parasitic capacitance induced by the base fins and the gate structures can be suppressed. As such, the process margin and the device performance can be improved at the same time. Moreover, the thicknesses of the top dielectric layers in different locations can be modified, so as to further improve both the process margin and the device performance. Furthermore, the thicknesses of the top dielectric layers may also be modified to optimize the process margin and the device performance of the devices with different active region widths (or channel width). For example, the devices with larger active region widths may have thinner top dielectric layers to facilitate the channel release process, and the devices with smaller active region widths may have thicker top dielectric layers to suppress the parasitic capacitance.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise indicated.

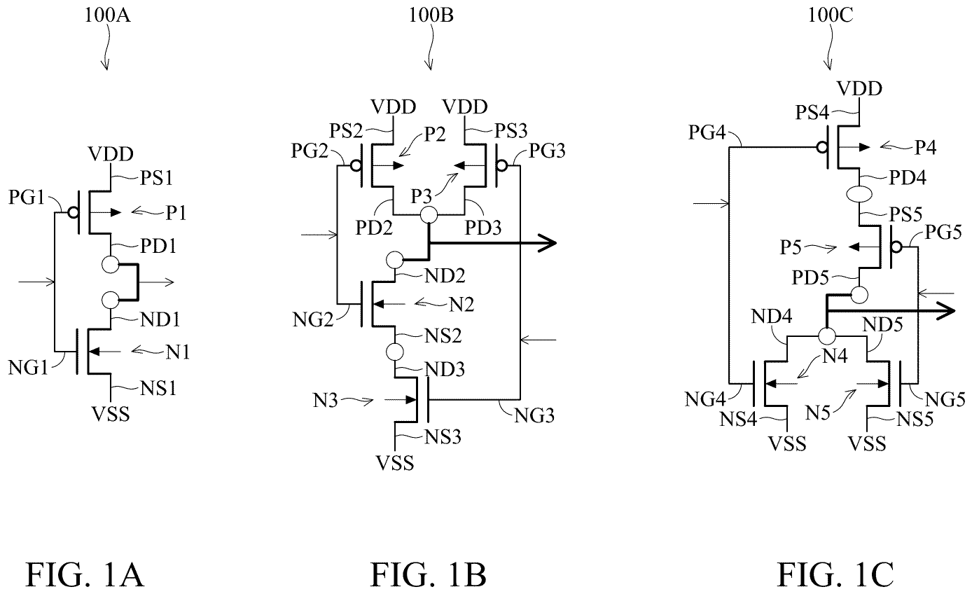

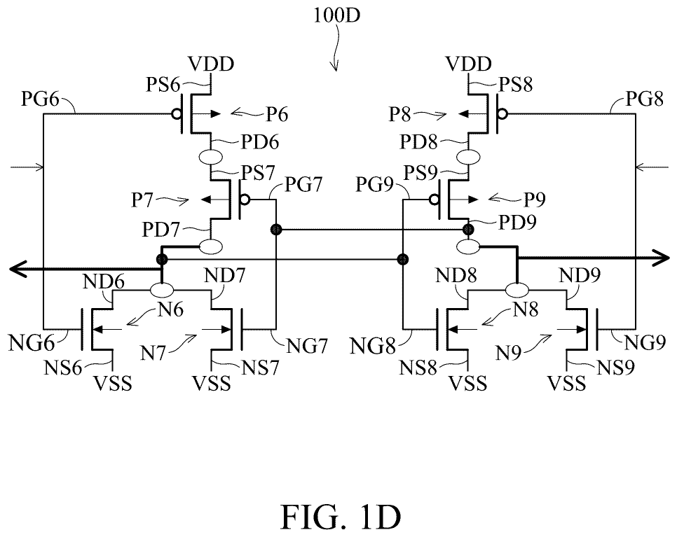

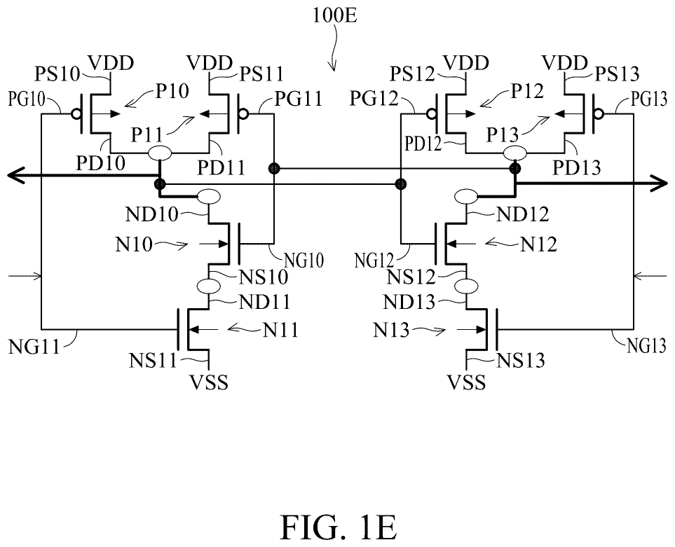

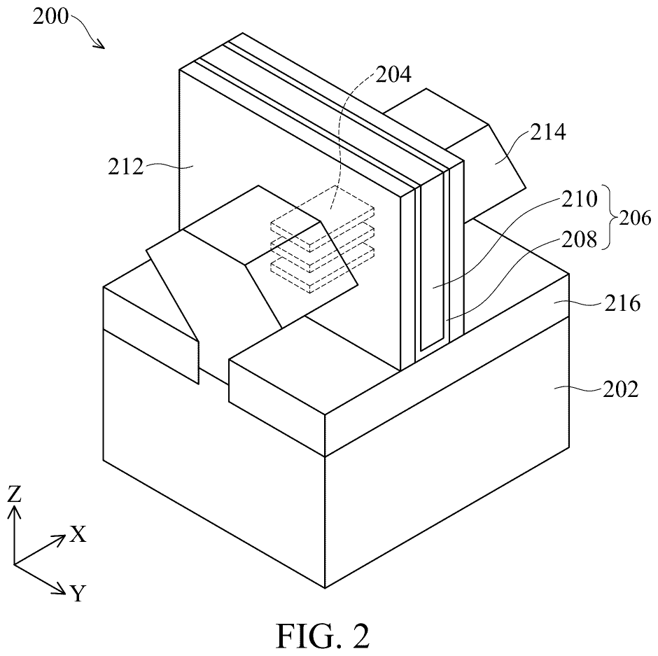

FIGS. 1A to 1E are circuit schematics of various standard (STD) cells which may be formed in an array of circuit cells in a logic region of an IC chip, in accordance with some embodiments. FIG. 1A illustrates an inverter 100A including an n-type transistor N1 and a P-type transistor P1. The n-type transistor N1 includes a source terminal NS1, a drain terminal ND1, and a gate terminal NG1. The P-type transistor P1 includes a source terminal PS1, a drain terminal PD1, and a gate terminal PG1.

As shown in FIG. 1A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 1B illustrates a NAND (also referred to as a NAND logic gate, a NAND device or a NAND cell) 100B including n-type transistors N2, N3 and p-type transistors P2, P3. The n-type transistor N2 includes a source terminal NS2, a drain terminal ND2, and a gate terminal NG2, and the n-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 1B, the gate terminals NG2 and PG2 are coupled with each other to operate as a first input terminal of the NAND 100B. The gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as “common drain.” The source terminals PS2 and PS3 are coupled to the VDD voltage. The source terminal NS3 is coupled to the VSS voltage. The source terminal NS2 and drain terminal ND3 are coupled with each other.

FIG. 1C illustrates a NOR (also referred to as a NOR logic gate, a NOR device or a NOR cell) 100C including n-type transistors N4, N5 and P-type transistors P4, P5. The n-type transistor N4 includes a source terminal NS4, a drain terminal ND4, and a gate terminal NG4, and the n-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 1C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage. The source terminal PS5 and drain terminal PD4 are coupled with each other.

FIG. 1D illustrates a flip-flop (also referred to as a flip-flop device or a flip-flop cell) 100D including n-type transistors N6, N7, N8, N9 and P-type transistors P6, P7, P8, P9. The n-type transistor N6 includes a source terminal NS6, a drain terminal ND6, and a gate terminal NG6, and the n-type transistor N7 includes a source terminal NS7, a drain terminal ND7, and a gate terminal NG7. The n-type transistor N8 includes a source terminal NS8, a drain terminal ND8, and a gate terminal NG8, and the n-type transistor N9 includes a source terminal NS9, a drain terminal ND9, and a gate terminal NG9. The P-type transistor P6 includes a source terminal PS6, a drain terminal PD6, and a gate terminal PG6, and the P-type transistor P7 includes a source terminal PS7, a drain terminal PD7, and a gate terminal PG7. The P-type transistor P8 includes a source terminal PS8, a drain terminal PD8, and a gate terminal PG8, and the P-type transistor P9 includes a source terminal PS9, a drain terminal PD9, and a gate terminal PG9.

As shown in FIG. 1D, the flip-flop 100D is a set-reset (SR) NOR latch. The NOR latch may include a pair of cross-coupled NOR. Specifically, the output terminal of a first NOR is coupled to the second input terminal of a second NOR, and the output terminal of the second NOR is coupled to the second input terminal of the first NOR. The details of the other connections of the flip-flop 100D are similar to the NOR 100C, and may not be described in detail herein.

FIG. 1E illustrates a flip-flop 100E including n-type transistors N10, N11, N12, N13 and P-type transistors P10, P11, P12, P13. The n-type transistor N10 includes a source terminal NS10, a drain terminal ND10, and a gate terminal NG10, and the n-type transistor N11 includes a source terminal NS11, a drain terminal ND11, and a gate terminal NG11. The n-type transistor N12 includes a source terminal NS12, a drain terminal ND12, and a gate terminal NG12, and the n-type transistor N13 includes a source terminal NS13, a drain terminal ND13, and a gate terminal NG13. The P-type transistor P10 includes a source terminal PS10, a drain terminal PD10, and a gate terminal PG10, and the P-type transistor P11 includes a source terminal PS11, a drain terminal PD11, and a gate terminal PG11. The P-type transistor P12 includes a source terminal PS12, a drain terminal PD12, and a gate terminal PG12, and the P-type transistor P13 includes a source terminal PS13, a drain terminal PD13, and a gate terminal PG13.

As shown in FIG. 1E, the flip-flop 100E is a SR NAND latch. The NAND latch may include a pair of cross-coupled NAND. Specifically, the output terminal of a first NAND is coupled to the first input terminal of a second NAND, and the output terminal of the second NAND is coupled to the first input terminal of the first NAND. The details of the other connections of the flip-flop 100E are similar to the NAND 100B, and may not be described in detail herein.

Each of the circuit cells discussed above is constructed by transistors. The transistors may be planar transistors, fin field-effect transistor (FinFET) transistors, GAA transistors, or a combination thereof. For the sake of providing an example, an exemplary GAA transistor is illustrated in FIG. 2. However, it should be understood that, the present disclosure should not be limited to a particular type of device, except as specifically claimed.

Referring to FIG. 2, a perspective view of an exemplary GAA transistor 200 is illustrated. The GAA transistor 200 is formed over a substrate 202. The substrate 202 may contains a semiconductor material, such as bulk silicon (Si). The GAA transistor 200 also includes one or more nanostructures 204 (dash lines) extending in the X-direction and vertically stacked (or arranged) in the Z-direction. More specifically, the nanostructures 204 are spaced apart from each other in the Z-direction. In some embodiments, the nanostructures 204 may also be referred to as channels, channel layers, nanosheets, or nanowires.

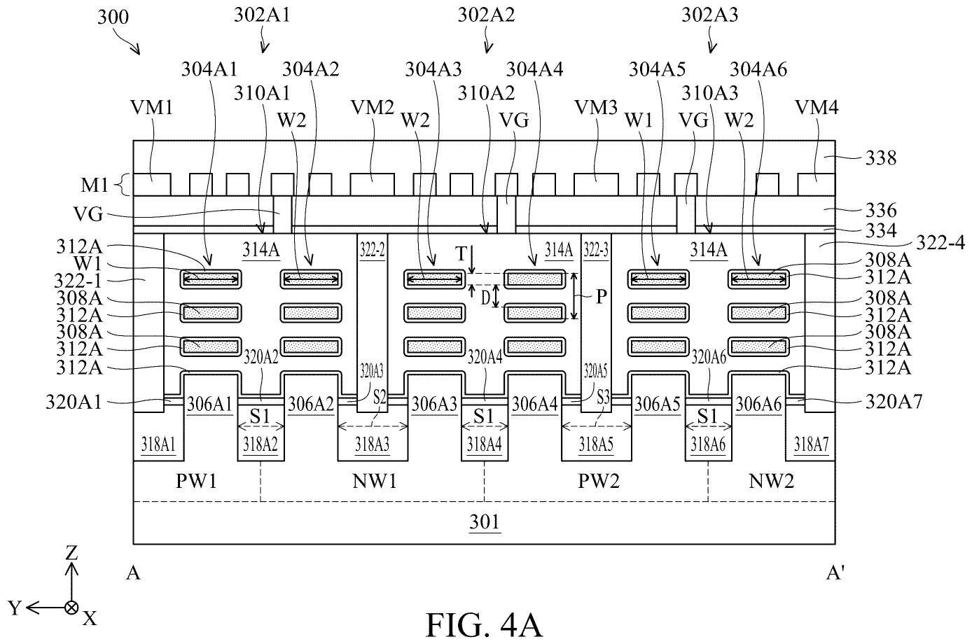

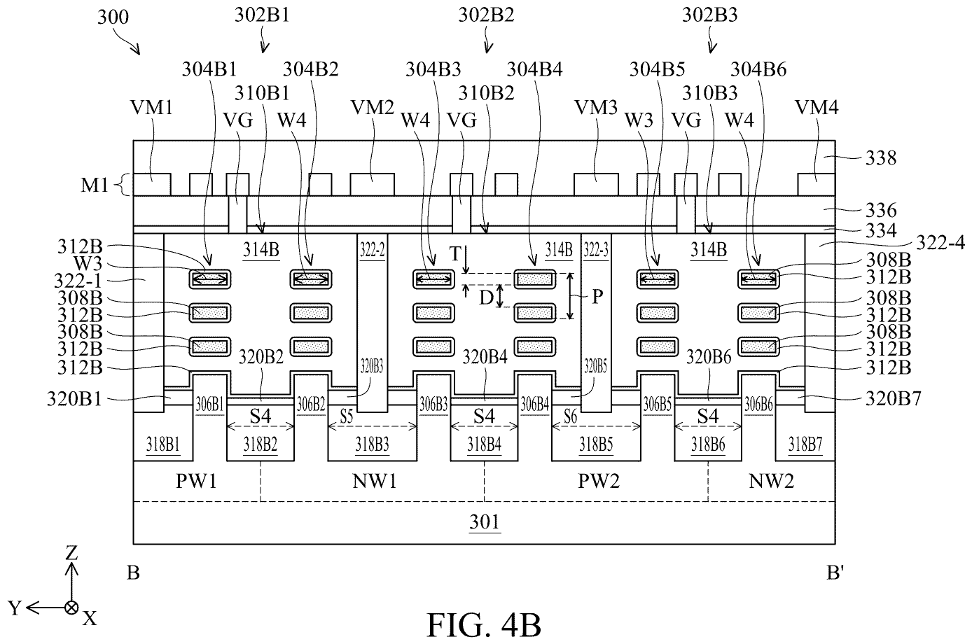

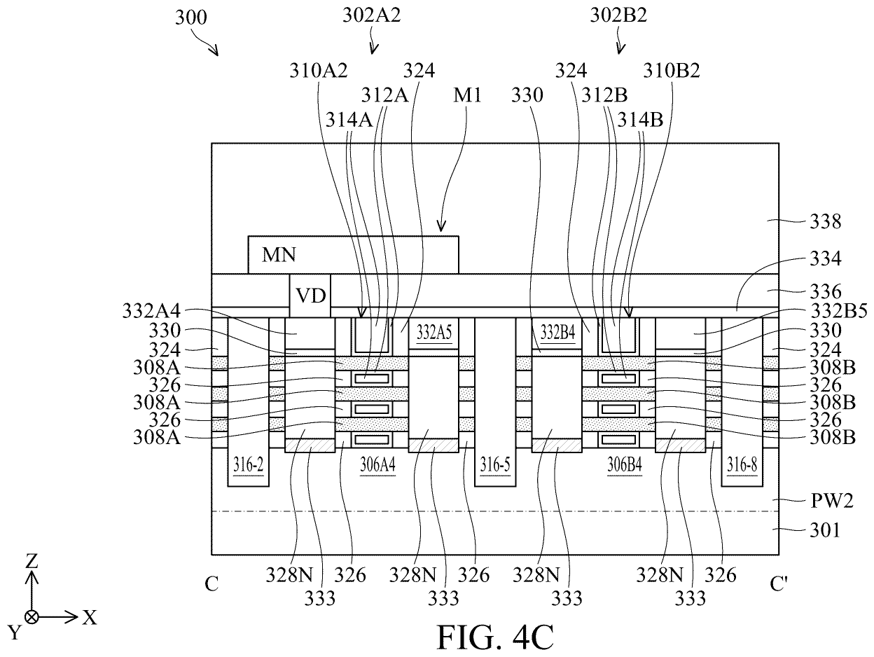

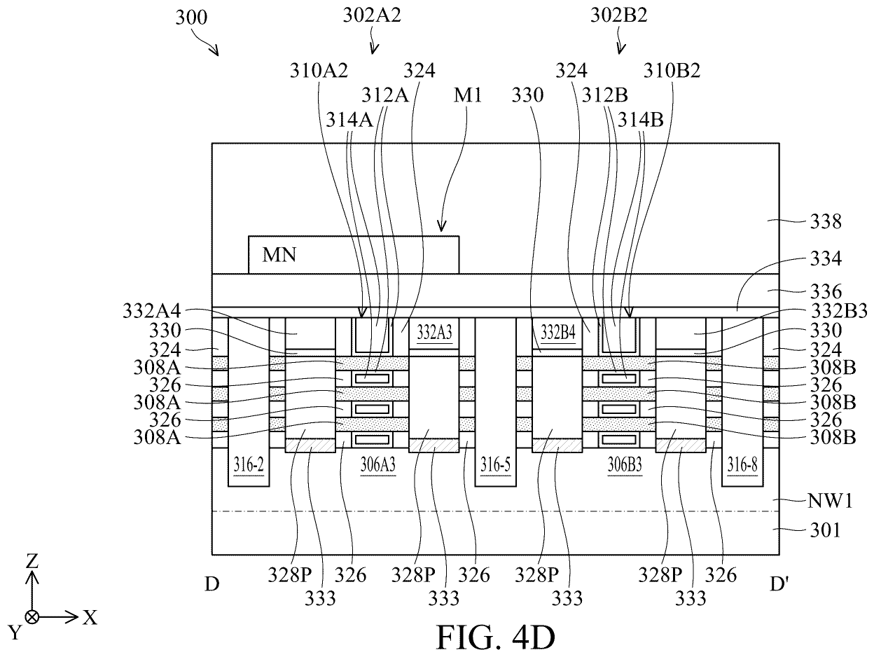

The GAA transistor 200 further includes a gate structure 206 including a gate dielectric layer 208 and a gate electrode 210. The gate dielectric layer 208 is wrapped around the nanostructures 204 and the gate electrode 210 is wrapped around the gate dielectric layer 208 (not shown in FIG. 2, may refer to FIGS. 4A and 4B). As shown in FIG. 2, gate spacers 212 are disposed on sidewalls of the gate structure 206 and over the nanostructures 204 (not shown in FIG. 2, may refer to FIGS. 4C and 4D).

The GAA transistor 200 further includes source/drain features 214. As shown in FIG. 2, two source/drain features 214 are formed on the opposite sides of the gate structure 206. The nanostructures 204 (dash lines) extend in the X-direction to connect one source/drain feature 214 to the other source/drain feature 214. The source/drain features 214 may also be referred to as source/drain, or source/drain regions. In some embodiments, source/drain feature(s) may refer to a source or a drain, individually or collectively dependent upon the context.

The isolation structures 216 are formed over the substrate 202 and under the gate dielectric layer 208, the gate electrode 210, and the gate spacers 212. The isolation structures 216 are used for isolating the GAA transistor 200 from other devices. In some embodiments, the isolation structures 216 include different structures, such as shallow trench isolation (STI) structures or deep trench isolation (DTI) structures. Therefore, the isolation structures 216 are also referred as to as STI features or DTI features.

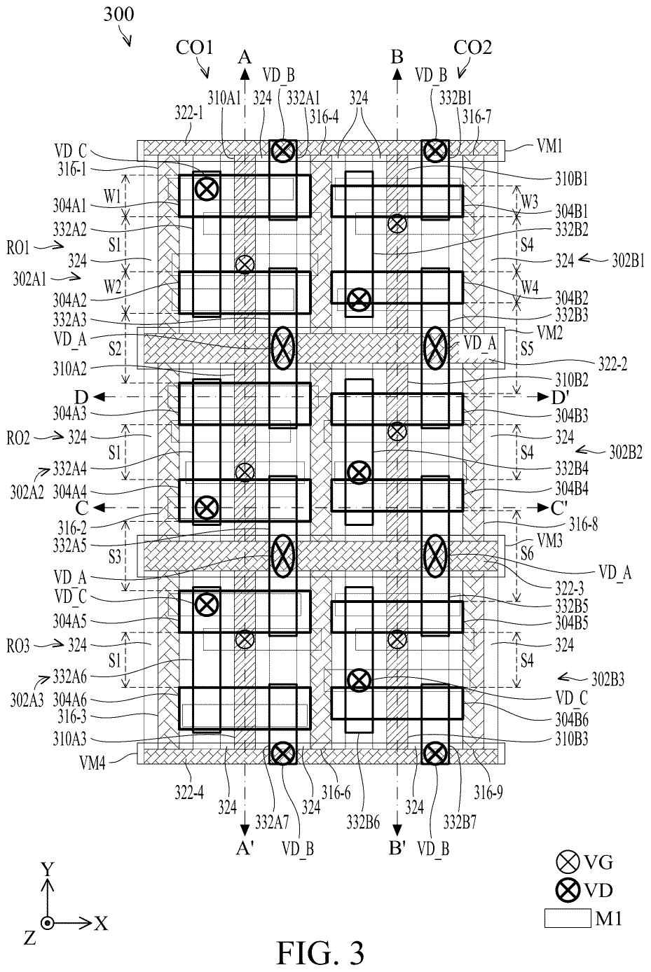

FIG. 3 illustrates a top view (or a layout) of a semiconductor device 300 that may be disposed in a logic region of an IC chip, in accordance with some embodiments. FIG. A and FIG. 4B illustrate Y-Z cross-sectional views of the semiconductor device 300 along line A-A′ and line B-B′ of FIG. 3, respectively, in accordance with some embodiments. FIG. 4C and FIG. 4D illustrate X-Z cross-sectional views of the semiconductor device 300 along line C-C′ and line D-D′ of FIG. 3, respectively, in accordance with some embodiments.

The semiconductor device 300 may include circuit cells, for example standard circuit cells (also referred to STD cells). The STD cells may include logic circuits or logic devices, including but not limited to logic circuits such as inverters, NANDs, NORs, flip-flops, or a combination thereof. For the sake of providing an example, the semiconductor device 300 shows an array of circuit cells with a row RO1 having circuit cells 302A1 and 302B1, a row RO2 having circuit cells 302A2 and 302B2, and a row RO3 having circuit cells 302A3 and 302B3. The circuit cells 302A1, 302A2, and 302A3 are arranged in a column CO1 in the Y-direction, and the circuit cells 302B1, 302B2, and 302B3 are arranged in a column CO2 in the Y-direction. The circuit cells 302A1, 302A2, 302A3, 302B1, 302B2, and 302B3 may be complementary metal-oxide-semiconductor (CMOS) transistor devices or inverters. It should be understood that, the circuit cells 302A1, 302A2, 302A3, 302B1, 302B2, and 302B3 are merely examples. The present disclosure applies to other types of STD cells as well, for example cells including NORs, ANDs, ORs, flip-flops, or a combination thereof.

The semiconductor device 300 may include active regions 304A1 to 304A6 (may be collectively referred to as active regions 304A) that extend lengthwise in the X-direction. More specifically, the circuit cell 302A1 includes active regions 304A1 and 304A2, the circuit cell 302A2 includes active regions 304A3 and 304A4, and the circuit cell 302A3 includes active regions 304A5 and 304A6. The semiconductor device 300 may further include active regions 304B1 to 304B6 (may be collectively referred to as active regions 304B) that extend lengthwise in the X-direction. More specifically, the circuit cell 302B1 includes active regions 304B1 and 304B2, the circuit cell 302B2 includes active regions 304B3 and 304B4, and the circuit cell 302B3 includes active regions 304B5 and 304B6. Each of active regions 304A and 304B includes channel regions, source regions, and drain regions (where source regions and drain regions are collectively referred to as source/drain regions herein) of transistors (e.g., the GAA transistor 200) of the array of the semiconductor device 300.

Referring to FIGS. 4A to 4D, the semiconductor device 300 includes a substrate 301, over which the various features are formed. The substrate 301 may contains a semiconductor material, such as bulk silicon (Si). In other embodiments, the substrate 301 may include other semiconductors, such as germanium (Ge), silicon germanium (SiGe), or a III-V semiconductor material. Example III-V semiconductor materials may include GaAs, InP, GaP, GaN, GaAsP, AlInAs, AlGaAs, GaInP, and InGaAs. Alternatively, the substrate 301 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

Still referring to FIGS. 4A to 4D, n-type wells NW1 and NW2 and p-type wells PW1 and PW2 are formed in or on the substrate 301. In some embodiments, the p-type wells PW1 and PW2 are configured for n-type transistors, and the n-type wells NW1 and NW2 are configured for p-type transistors. The n-type wells NW1 and NW2 are doped with n-type dopants to have an n-type conductivity type, such as phosphorus (P), arsenic (As), other n-type dopant, or combinations thereof. The p-type wells PW1 and PW2 are doped with p-type dopants to have a p-type conductivity type, such as boron (B), indium (In), other p-type dopant, or combinations thereof.

In some embodiments, the active regions 304A1 and 304B1 are disposed in the p type well PW1, the active regions 304A2, 304A3, 304B2, and 304B3 are disposed in the n-type well NW1, the active regions 304A4, 304A5, 304B4, and 304B5 are disposed in the p-type well PW2, and the active regions 304A6 and 304B6 are disposed in the n-type well NW2. The n-type wells NW1 and NW2 and the p-type wells PW1 and PW2 are arranged alternately in the Y-direction, as shown in FIGS. 4A and 4B. In some embodiments, the active regions 304A1 to 304A6 respectively have base fins 306A1 to 306A6 (may be collectively referred to as base fins 306A) protruded from the substrate 301, as shown in FIG. 4A. In some embodiments, the active regions 304B1 to 304B6 respectively have base fins 306B1 to 306B6 (may be collectively referred to as base fins 306B) protruded from the substrate 301, as shown in FIG. 4B.

In some embodiments, the active regions 304A1 to 304A6 are spaced apart from each other in the Y-direction. More specifically, the active regions 304A in different wells are separated by a spacing S1, the active regions 304A in the same n-type well are separated by a spacing S2, and the active regions 304A in the same p-type well are separated by a spacing S3. For example, in the Y-direction, the active region 304A1 in the p-type well PW1 and the active region 304A2 in the n-type well NW1 are separated by the spacing S1, the active region 304A3 in the n-type well NW1 and the active region 304A4 in the p-type well PW2 are separated by the spacing S1, and the active region 304A5 in the p-type well PW2 and the active region 304A6 in the n-type well NW2 are separated by the spacing S1, as shown in FIG. 3. For example, in the Y-direction, the active regions 304A2 and 304A3 in the n-type well NW1 are separated by the spacing S2, and the active regions 304A4 and 304A5 in the p-type well PW2 are separated by the spacing S3, as shown in FIG. 3. In some embodiments, the spacing S1 is less than the spacing S2 and the spacing S3. In other embodiments, the spacing S1 is the same as or greater than the spacing S2 and the spacing S3.

As described above, the active regions 304A1 to 304A6 respectively have base fins 306A1 to 306A6. As such, the base fins 306A1 to 306A6 in the active regions 304A1 to 304A6 are also spaced apart from each other by the spacing S1, the spacing S2, or the spacing S3 in the Y-direction. For example, in the Y-direction, the base fin 306A1 in the p-type well PW1 and the base fin 306A2 in the n-type well NW1 are separated by the spacing S1, the base fin 306A3 in the n-type well NW1 and the base fin 306A4 in the p-type well PW2 are separated by the spacing S1, and the base fin 306A5 in the p-type well PW2 and the base fin 306A6 in the n-type well NW2 are separated by the spacing S1, as shown in FIG. 4A. For example, in the Y-direction, the base fins 306A2 and 306A3 in the n-type well NW1 are separated by the spacing S2, and the base fins 306A4 and 306A5 in the p-type well PW2 are separated by the spacing S3, as shown in FIG. 4A.

In some embodiments, the active regions 304B1 to 304B6 are spaced apart from each other in the Y-direction. More specifically, the active regions 304B in different wells are separated by a spacing S4, the active regions 304B in the same n-type well are separated by a spacing S5, and the active regions 304B in the same p-type well are separated by a spacing S6. For example, in the Y-direction, the active region 304B1 in the p-type well PW1 and the active region 304B2 in the n-type well NW1 are separated by the spacing S4, the active region 304B3 in the n-type well NW1 and the active region 304B4 in the p-type well PW2 are separated by the spacing S4, and the active region 304B5 in the p-type well PW2 and the active region 304B6 in the n-type well NW2 are separated by the spacing S4, as shown in FIG. 3. For example, in the Y-direction, the active regions 304B2 and 304B3 in the n-type well NW1 are separated by the spacing S5, and the active regions 304B4 and 304B5 in the p-type well PW2 are separated by the spacing S6, as shown in FIG. 3.

In some embodiments, the spacing S5 and the spacing S6 are greater than the spacing S4. In further embodiments, the ratio of spacing S5 to spacing S4 and the ratio of spacing S6 to spacing S4 are in a range from about 1.1 to about 2. In some embodiments, the spacing S4 is substantially the same as the spacing S1. In some embodiments, the spacing S5 is greater than the spacing S2, and the spacing S6 is greater than the spacing S3. In further embodiments, the ratio of spacing S5 to spacing S2 and the ratio of spacing S6 to spacing S3 are in a range from about 1.1 to about 2. In some embodiments, the spacing S1 and the spacing S4 are in a range from about 15 nm to about 50 nm.

As described above, the active regions 304B1 to 304B6 respectively have base fins 306B1 to 306B6. As such, the base fins 306B1 to 306B6 in the active regions 304B1 to 304B6 are also spaced apart from each other by the spacing S4, the spacing S5, or the spacing S6 in the Y-direction. For example, in the Y-direction, the base fin 306B1 in the p-type well PW1 and the base fin 306B2 in the n-type well NW1 are separated by the spacing S4, the base fin 306B3 in the n-type well NW1 and the base fin 306B4 in the p-type well PW2 are separated by the spacing S4, and the base fin 306B5 in the p-type well PW2 and the base fin 306B6 in the n-type well NW2 are separated by the spacing S4, as shown in FIG. 4B. For example, in the Y-direction, the base fins 306B2 and 306B3 in the n-type well NW1 are separated by the spacing S5, and the base fins 306B4 and 306B5 in the p-type well PW2 are separated by the spacing S6, as shown in FIG. 4B.

Each of the transistors in the circuit cells 302A1-302A3 and 302B1-302B3 may include nanostructures 308 similar to the nanostructures 204 discussed above. More specifically, each of the active regions 304A and 304B has the nanostructures 308 in the channel regions of the active regions 304A and 304B. The nanostructures 308 may include nanostructures 308A disposed over the base fins 306A1 to 306A6 of the active regions 304A (see FIG. 4A), and include nanostructures 308B disposed over the base fins 306B1 to 306B6 of the active regions 304B (see FIG. 4B). As shown in FIGS. 4A to 4D, the nanostructures 308A are alternately stacked over the base fins 306A1 to 306A6, and the nanostructures 308B are alternately stacked over the base fins 306B1 to 306B6.

In some embodiments, in the Y-direction, the nanostructures 308A disposed over the base fin 306A1 have a width W1 and the nanostructures 308A disposed over the base fin 306A2 have a width W2. In further embodiments, the nanostructures 308A disposed over the base fins 306A4 and 306A5 also have the width W1, and the nanostructures 308A disposed over the base fins 306A3 and 306A6 also have the width W2. In further embodiments, the base fins 306A1, 306A4 and 306A5 also have the width W1, and the base fins 306A2, 306A3 and 306A6 also have the width W2. In some embodiments, in the Y-direction, the nanostructures 308B disposed over the base fin 306B1 have a width W3 and the nanostructures 308B disposed over the base fin 306B2 have a width W4. In further embodiments, the nanostructures 308B disposed over the base fins 306B4 and 306B5 also have the width W3, and the nanostructures 308B disposed over the base fins 306B3 and 306B6 also have the width W4. In further embodiments, the base fins 306B1, 306B4 and 306B5 also have the width W3, and the base fins 306B2, 306B3 and 306B6 also have the width W4.

In some embodiments, the width W1 is greater than the width W3, and the width W2 is greater than the width W4. That is, the active regions 304A of the circuit cells 302A1 to 302A3 are wider than the active regions 304B of the circuit cells 302B1 to 302B3. For example, the active regions 304A1, 304A4, and 304A5 (having the width W1) are wider than the active regions 304B1, 304B4, and 304B5 (having the width W3), and the active regions 304A2, 304A3, and 304A6 (having the width W2) are wider than the active regions 304B2, 304B3, and 304B6 (having the width W4). In some embodiments, the ratio of width W1 to width W3 and the ratio of width W2 to width W4 are in a range from about 1.2 to about 4.

In some embodiments, three nanostructures 308 are vertically stacked (or vertically arranged) from each other in the Z-direction for one transistor. However, there may be another appropriate number of nanostructures in one transistor. For example, there may be from 2 to 10 nanostructures 308 in one transistor. The nanostructures 308 further extend lengthwise in the X-direction (see FIGS. 4C and 4D) and widthwise in the Y-direction (see FIGS. 4A and 4B). In some embodiments, each of the nanostructures 308 has a thickness T in the Z-direction and in a range from about 3 nm to about 8 nm, as shown in FIGS. 4A and 4B. In some embodiments, the nanostructures 308 are spaced apart from each other in the Z-direction by a distance D in a range from about 4 nm to about 15 nm, as shown in FIGS. 4A and 4B. In some embodiments, the nanostructures 308 vertically have a pitch P in the Z-direction and in a range from about 7 nm to about 23 nm.

In some embodiments, the circuit cells 302A1 to 302A3 respectively include gate structures 310A1 to 310A3 (may be collectively referred to as gate structures 310A), and the circuit cells 302B1 to 302B3 respectively include gate structures 310B1 to 310B3 (may be collectively referred to as gate structures 310B). The gate structures 310A1 to 310A3 may extend lengthwise in the Y-direction and be separated from each other in the Y-direction. The gate structures 310A1 to 310A3 may be also arranged in the Y-direction and aligned in the Y-direction. Similarly, the gate structures 310B1 to 310B3 may extend lengthwise in the Y-direction and be separated from each other in the Y-direction. The gate structures 310B1 to 310B3 may be also arranged in the Y-direction and aligned in the Y-direction.

In some embodiments, the gate structures 310A1 to 310A3 are disposed over the channel regions of the respective active regions 304A1 to 304A6 (i.e., the nanostructures 308A) and between the respective source/drain regions of the active regions 304A1 to 304A6 (i.e., p-type source/drain features or n-type source/drain features). In some embodiments, gate structures 310A1 to 310A3 are wrapped around the vertically stacked nanostructures 308A in the channel regions of the active regions 304A1 to 304A6, respectively (as shown in FIG. 4A). More specifically, the gate structure 310A1 is wrapped around the nanostructures 308A in the active regions 304A1 and 304A2, the gate structure 310A2 is wrapped around the nanostructures 308A in the active regions 304A3 and 304A4, and the gate structure 310A3 is wrapped around the nanostructures 308A in the active regions 304A5 and 304A6.

The active regions 304A1 to 304A6 and the gate structures 310A1 to 310A3 may be configured to provide circuit cells 302A1 to 302A3 with transistors. For example, in the circuit cell 302A1, the gate structure 310A1 engages the active region 304A1 and the active region 304A2 to construct an n-type transistor and a p-type transistor. For example, in the circuit cell 302A2, the gate structure 310A2 engages the active region 304A3 and the active region 304A4 to construct a p-type transistor and an n-type transistor. For example, in the circuit cell 302A3, the gate structure 310A3 engages the active region 304A5 and the active region 304A6 to construct an n-type transistor and a p-type transistor.

In some embodiments, the gate structures 310B1 to 310B3 are disposed over the channel regions of the respective active regions 304B1 to 304B6 (i.e., the nanostructures 308B) and between the respective source/drain regions of the active regions 304B1 to 304B6 (i.e., p-type source/drain features or n-type source/drain features). In some embodiments, gate structures 310B1 to 310B3 are wrapped around the vertically stacked nanostructures 308B in the channel regions of the active regions 304B1 to 304B6, respectively (as shown in FIG. 4B). More specifically, the gate structure 310B1 is wrapped around the nanostructures 308B in the active regions 304B1 and 304B2, the gate structure 310B2 is wrapped around the nanostructures 308B in the active regions 304B3 and 304B4, and the gate structure 310B3 is wrapped around the nanostructures 308B in the active regions 304B5 and 304B6.

The active regions 304B1 to 304B6 and the gate structures 310B1 to 310B3 may be configured to provide circuit cells 302B1 to 302B3 with transistors. For example, in the circuit cell 302B1, the gate structure 310B1 engages the active region 304B1 and the active region 304B2 to construct an n-type transistor and a p-type transistor, respectively. For example, in the circuit cell 302B2, the gate structure 310B2 engages the active region 304B3 and the active region 304B4 to construct a p-type transistor and an n-type transistor. For example, in the circuit cell 302B3, the gate structure 310B3 engages the active region 304B5 and the active region 304B6 to construct an n-type transistor and a p-type transistor.

In some embodiments, each of the n-type transistors is arranged with one p-type transistor in the Y-direction and share one gate structure with that p-type transistor, as shown in FIGS. 3, 4A, and 4B. For example, in the circuit cell 302A1, the n-type transistor (formed from the active region 304A1) and the p-type transistor (formed from the active region 304A2) are arranged in the Y-direction and share the gate structure 310A1. In the circuit cell 302A2, the p-type transistor (formed from the active region 304A3) and the n-type transistor (formed from the active region 304A4) are arranged in the Y-direction and share the gate structure 310A2. In the circuit cell 302A3, the n-type transistor (formed from the active region 304A5) and the p-type transistor (formed from the active region 304A6) are arranged in the Y-direction and share the gate structure 310A3. For example, in the circuit cell 302B1, the n-type transistor (formed from the active region 304B1) and the p-type transistor (formed from the active region 304B2) are arranged in the Y-direction and share the gate structure 310B1. In the circuit cell 302B2, the p-type transistor (formed from the active region 304B3) and the n-type transistor (formed from the active region 304B4) are arranged in the Y-direction and share the gate structure 310B2. In the circuit cell 302B3, the n-type transistor (formed from the active region 304B5) and the p-type transistor (formed from the active region 304B6) are arranged in the Y-direction and share the gate structure 310B3.

In some embodiments, the semiconductor device 300 further includes gate isolation structures 316 for separating the circuit cells 302A1 to 302A3 and 302B1 to 302B3 from other devices or circuit cells (not shown). The gate isolation structures 316 may include gate isolation structures 316-1 to 316-9 extending lengthwise in the Y-direction. In some embodiments, in the row RO1 of the semiconductor device 300, the circuit cell 302A1 is disposed between the gate isolation structures 316-1 and 316-4 in the X-direction, and the circuit cell 302B1 is disposed between the gate isolation structures 316-4 and 316-7 in the X-direction. In these embodiments, in the X-direction, the gate isolation structures 316-4 may space apart the active region 304A1 from the active region 304B1 and space apart the active region 304A2 from the active region 304B2.

In some embodiments, in the row RO2 of the semiconductor device 300, the circuit cell 302A2 is disposed between the gate isolation structures 316-2 and 316-5 in the X-direction, and the circuit cell 302B2 is disposed between the gate isolation structures 316-5 and 316-8 in the X-direction. In these embodiments, in the X-direction, the gate isolation structures 316-5 may space apart the active region 304A3 from the active region 304B3 and space apart the active region 304A4 from the active region 304B4. In some embodiments, in the row RO3 of the semiconductor device 300, the circuit cell 302A3 is disposed between the gate isolation structures 316-3 and 316-6 in the X-direction, and the circuit cell 302B3 is disposed between the gate isolation structures 316-6 and 316-9 in the X-direction. In these embodiments, in the X-direction, the gate isolation structures 316-6 may space apart the active region 304A5 from the active region 304B5 and space apart the active region 304A6 from the active region 304B6.

In some embodiments, the semiconductor device 300 further includes isolation structures 318 and top dielectric layers 320 formed on the isolation structures 318. The isolation structures 318 and the top dielectric layers 320 are formed over the substrate 301 and configured to isolate the adjacent active regions. The isolation structures 318 may include isolation structures 318A1 to 318A7 (may be collectively referred to as isolation structures 318A) disposed in the column CO1 of the semiconductor device 300, and include isolation structures 318B1 to 318B7 (may be collectively referred to as isolation structures 318B) disposed in the column CO2 of the semiconductor device 300. The top dielectric layers 320 may include top dielectric layers 320A1 to 320A7 (may be collectively referred to as top dielectric layers 320A) respectively formed on the isolation structures 318A1 to 318A7, and include top dielectric layers 320B1 to 320B7 (may be collectively referred to as top dielectric layers 320B) respectively formed on the isolation structures 318B1 to 318B7.

In some embodiments, the isolation structures 318 may include different structures, such as STI structures, DTI structures, and/or local oxidation of silicon (LOCOS) structures. In some embodiments, the isolation structures 318 may include or be made of an oxide-based material, such as silicon oxide (SiO₂). In some embodiments, the top dielectric layers 320 may include nitrogen, such that the top dielectric layers 320 may also be referred to as nitrogen content dielectric layers 320. The top dielectric layers 320 may include a dielectric material having higher k value (dielectric constant) than the isolation structures 318. In some embodiments, the top dielectric layers 320 are silicon nitride-based layers (e.g., Si₃N₄). In other embodiments, the top dielectric layers 320 include or are made of SiON, SiOCN, or combinations thereof. In further embodiments, the semiconductor device 300 further includes liner layers formed before the formation of the isolation structures 318, such that the liner layers are formed on sidewalls and bottom surfaces of the isolation structures 318.

In some embodiments, the top dielectric layers 320 may include multi-layer structures. For example, each of the top dielectric layers 320 may include a first dielectric layer formed on the isolation structures 318 and a second dielectric layer formed on the first dielectric layer. In some embodiments, both of the first dielectric layer and the second dielectric layer are nitrogen content dielectric layers, and the nitrogen concentration in the second dielectric layer is higher than nitrogen concentration in the first dielectric layer.

In some embodiments, the isolation structures 318A and the top dielectric layers 320A are disposed between the active regions 304A in the Y-direction. For example, the isolation structures 318A1 and the top dielectric layers 320A1 may be disposed between a base fin of an active region of other circuit cell and the base fins 306A1 in the p-type well PW1. The isolation structures 318A2 and the top dielectric layers 320A2 may be disposed between the base fins 306A1 in the p-type well PW1 and the base fins 306A2 in the n-type well NW1. The isolation structures 318A3 and the top dielectric layers 320A3 may be disposed between the base fins 306A2 and 306A3 in the n-type well NW1. The isolation structures 318A4 and the top dielectric layers 320A4 may be disposed between the base fins 306A3 in the n-type well NW1 and the base fins 306A4 in the p-type well PW2. The isolation structures 318A5 and the top dielectric layers 320A5 may be disposed between the base fins 306A4 and 306A5 in the p-type well PW2. The isolation structures 318A6 and the top dielectric layers 320A6 may be disposed between the base fins 306A5 in the p-type well PW2 and the base fins 306A6 in the n-type well NW2. The isolation structures 318A7 and the top dielectric layers 320A7 may be disposed between the base fins 306A6 and a base fin of an active region of other circuit cell in the n-type well NW2.

In some embodiments, the isolation structures 318B and the top dielectric layers 320B are disposed between the active regions 304B in the Y-direction. For example, the isolation structures 318B1 and the top dielectric layers 320B1 may be disposed between a base fin of an active region of other circuit cell and the base fins 306B1 in the p-type well PW1. The isolation structures 318B2 and the top dielectric layers 320B2 may be disposed between the base fins 306B1 in the p-type well PW1 and the base fins 306B2 in the n-type well NW1. The isolation structures 318B3 and the top dielectric layers 320B3 may be disposed between the base fins 306B2 and 306B3 in the n-type well NW1. The isolation structures 318B4 and the top dielectric layers 320B4 may be disposed between the base fins 306B3 in the n-type well NW1 and the base fins 306B4 in the p-type well PW2. The isolation structures 318B5 and the top dielectric layers 320B5 may be disposed between the base fins 306B4 and 306B5 in the p-type well PW2. The isolation structures 318B6 and the top dielectric layers 320B6 may be disposed between the base fins 306B5 in the p-type well PW2 and the base fins 306B6 in the n-type well NW2. The isolation structures 318B7 and the top dielectric layers 320B7 may be disposed between the base fins 306B6 and a base fin of an active region of other circuit cell in the n-type well NW2.

As described above, the active regions 304A are separated from each other by the spacing S1, the spacing S2, or the spacing S3 in the Y-direction. Therefore, the isolation structures 318A and the top dielectric layers 320A also have corresponding lengths in the Y-direction. For example, the isolation structures 318A2, 318A4, and 318A6 and the top dielectric layers 320A2, 320A4, and 320A6 between the active regions 304A in the different wells may have the same length as the spacing S1 described above. The isolation structures 318A3 and 318A7 and the top dielectric layers 320A3 and 320A7 between the active regions 304A in the n-type wells may have the same length as the spacing S2 described above. The isolation structures 318A1 and 318A5 and the top dielectric layers 320A1 and 320A5 between the active regions 304A in the p-type wells may have the same length as the spacing S3 described above.

As described above, the active regions 304B are separated from each other by the spacing S4, the spacing S5, or the spacing S6 in the Y-direction. Therefore, the isolation structures 318B and the top dielectric layers 320B also have corresponding lengths in the Y-direction. The isolation structures 318B2, 318B4, and 318B6 and the top dielectric layers 320B2, 320B4, and 320B6 between the active regions 304B in the different wells may have the same length as the spacing S4 described above. The isolation structures 318B3 and 318B7 and the top dielectric layers 320B3 and 320B7 between the active regions 304B in the n-type wells may have the same length as the spacing S5 described above. The isolation structures 318B1 and 318B5 and the top dielectric layers 320B1 and 320B5 between the active regions 304B in the p-type wells may have the same length as the spacing S6 described above.

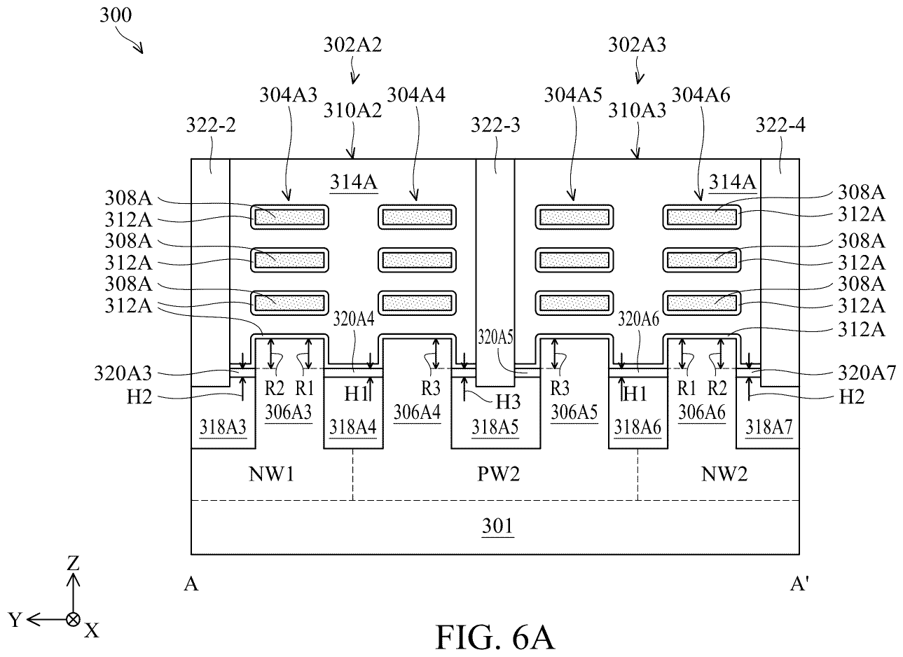

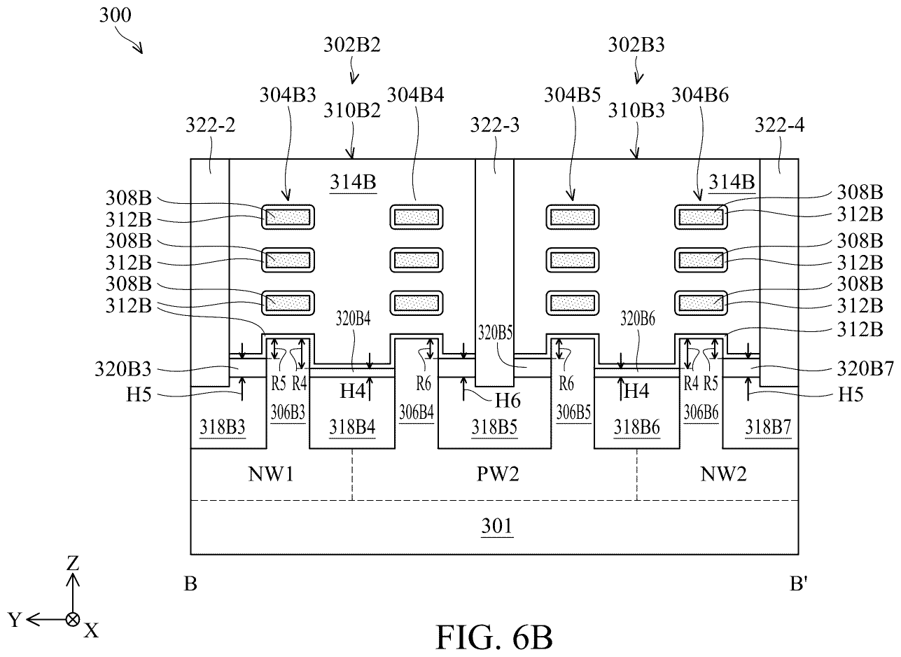

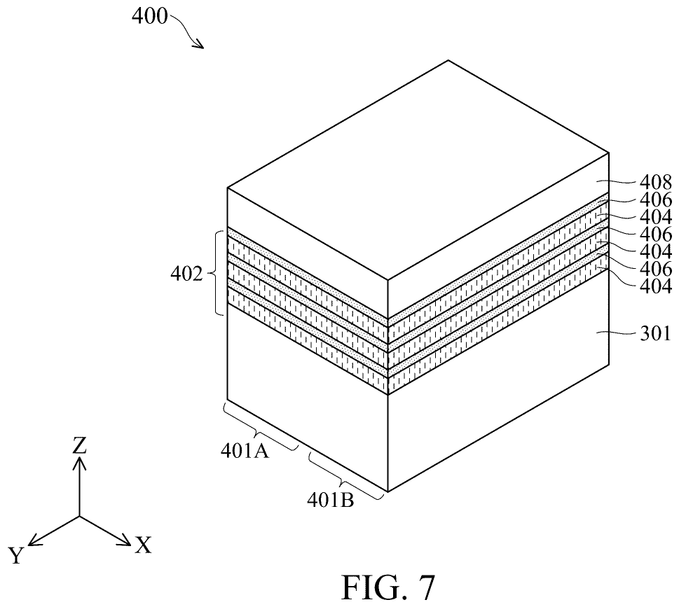

In some embodiments, the top dielectric layers 320A1 to 320A7 and 320B1 to 320B7 may have different thicknesses. In further embodiments, the thicknesses of the isolation structures 318A1 to 318A7 and 318B1 to 318B7 are substantially the same. FIG. 6A illustrates a partial enlarged cross-sectional view of the semiconductor device 300 of FIG. 4A, and FIG. 6B illustrates a partial enlarged cross-sectional view of the semiconductor device 300 of FIG. 4B, in accordance with some embodiments. For the sake of simplicity and clarity, FIG. 6A illustrates the partial enlarged cross-sectional view for the circuit cells 302A2 and 302A3, and FIG. 6B illustrates the partial enlarged cross-sectional view for the circuit cells 302B2 and 302B3.

Referring to FIGS. 4A and 6A, the top dielectric layer 320A2 over the p-type well PW1 and the n-type well NW1, the top dielectric layer 320A4 over the n-type well NW1 and the p-type well PW2, and the top dielectric layer 320A6 over the p-type well PW2 and the n-type well NW2 may each have a thickness H1. The top dielectric layer 320A3 over the n-type well NW1 and the top dielectric layer 320A7 over the n-type well NW2 may each have a thickness H2. The top dielectric layer 320A1 over the p-type well PW1 and the top dielectric layer 320A5 over the p-type well PW2 may each have a thickness H3. In some embodiments, the thicknesses H1, H2, and H3 are substantially the same. In other embodiments, the thicknesses H2 and H3 are greater than the thickness H1. In certain embodiments, the thicknesses H2 and H3 are less than the thickness H1.

Referring to FIGS. 4B and 6B, the top dielectric layer 320B2 over the p-type well PW1 and the n-type well NW1, the top dielectric layer 320B4 over the n-type well NW1 and the p-type well PW2, and the top dielectric layer 320B6 over the p-type well PW2 and the n-type well NW2 may each have a thickness H4. The top dielectric layer 320B3 over the n-type well NW1 and the top dielectric layer 320B7 over the n-type well NW2 may each have a thickness H5. The top dielectric layer 320B1 over the p-type well PW1 and the top dielectric layer 320B5 over the p-type well PW2 may each have a thickness H6.

In some embodiments, the thicknesses H4 of the top dielectric layers 320B2, 320B4, and 320B6 are less than the thicknesses H5 of the top dielectric layers 320B3 and 320B7 and the thicknesses H6 of the top dielectric layers 320B1 and 320B5. In some embodiments, the thickness H5 is substantially the same as the thickness H6. In other embodiments, the thickness H5 is different than the thickness H6. In some embodiments, the ratio of thickness H5 to thickness H4 is in a range from about 1.1 to about 4, and the ratio of thickness H6 to thickness H4 is in a range from about 1.1 to about 4.

In some embodiments, the thicknesses H4 of the top dielectric layers 320B2, 320B4, and 320B6 and thicknesses H1 of the top dielectric layers 320A2, 320A4, and 320A6 are substantially the same. In some embodiments, the thicknesses H5 of the top dielectric layers 320B3 and 320B7 are greater than the thicknesses H2 of the top dielectric layers 320A3 and 320A7. The ratio of thickness H5 to thickness H2 may be in a range from about 1.1 to about 4. In some embodiments, the thicknesses H6 of the top dielectric layers 320B1 and 320B5 are greater than the thicknesses H3 of the top dielectric layers 320A1 and 320A5. The ratio of thickness H6 to thickness H3 may be in a range from about 1.1 to about 4. In other embodiments, the thicknesses H4 of the top dielectric layers 320B2, 320B4, and 320B6 are greater than the thicknesses H1 of the top dielectric layers 320A2, 320A4, and 320A6. In these embodiments, the ratio of thickness H4 to thickness H1 is in a range from about 1 to about 1.5.

Referring to FIGS. 4A and 6A again, in the Z-direction, the distance between the top surface of the top dielectric layer 320A2 and the top surface of the base fin 306A1 or 306A2, the distance between the top surface of the top dielectric layer 320A4 and the top surface of the base fin 306A3 or 306A4, and the distance between the top surface of the top dielectric layer 320A6 and the top surface of the base fin 306A5 or 306A6 may be heights R1. In the Z-direction, the distance between the top surface of the top dielectric layer 320A3 and the top surface of the base fin 306A2 or 306A3, and the distance between the top surface of the top dielectric layer 320A7 and the top surface of the base fin 306A6 may be heights R2. In the Z-direction, the distance between the top surface of the top dielectric layer 320A1 and the top surface of the base fin 306A1, and the distance between the top surface of the top dielectric layer 320A5 and the top surface of the base fin 306A4 or 306A5 may be heights R3. In some embodiments, the heights R1, R2, and R3 are substantially the same. In other embodiments, the height R1 is greater than the heights R2 and R3. In certain embodiments, the height R1 is less than the heights R2 and R3.

Referring to FIGS. 4B and 6B again, in the Z-direction, the distance between the top surface of the top dielectric layer 320B2 and the top surface of the base fin 306B1 or 306B2, the distance between the top surface of the top dielectric layer 320B4 and the top surface of the base fin 306B3 or 306B4, and the distance between the top surface of the top dielectric layer 320B6 and the top surface of the base fin 306B5 or 306B6 may be heights R4. In the Z-direction, the distance between the top surface of the top dielectric layer 320B3 and the top surface of the base fin 306B2 or 306B3, and the distance between the top surface of the top dielectric layer 320B7 and the top surface of the base fin 306B6 may be heights R5. In the Z-direction, the distance between the top surface of the top dielectric layer 320B1 and the top surface of the base fin 306B1, and the distance between the top surface of the top dielectric layer 320B5 and the top surface of the base fin 306B4 or 306B5 may be heights R6.

In some embodiments, the height R4 is greater than the height R5 and the height R6. In some embodiments, the height R5 is substantially the same as the height R6. In other embodiments, the height R5 is different than the height R6. In some embodiments, the ratio of height R4 to height R5 is in a range from about 1.1 to about 3, and the ratio of height R4 to height R6 is in a range from about 1.1 to about 3.

Referring to FIGS. 4A, 4B, 6A, and 6B together, in some embodiments, the height R4 and the height R1 are substantially the same. In some embodiments, the height R2 is greater than the height R5. The ratio of height R2 to height R5 may be in a range from about 1.1 to about 3. In some embodiments, the height R3 is greater than the height R6. The ratio of height R3 to height R6 may be in a range from about 1.1 to about 3. In other embodiments, the height R1 is greater than the height R4.

As described above, the gate structures 310A engage the active regions 304A and the gate structures 310B engage the active regions 304B to construct the transistors. In some embodiments, each of the gate structures 310A1 to 310A3 has a gate dielectric layer 312A and a gate electrode layer 314A, and each of the gate structures 310B1 to 310B3 has a gate dielectric layer 312B and a gate electrode layer 314B. The gate dielectric layers 312A are wrapped around each of the nanostructures 308A, and the gate electrode layers 314A are wrapped around the gate dielectric layers 312A and the nanostructures 308A. The gate dielectric layers 312B are wrapped around each of the nanostructures 308B, and the gate electrode layers 314B are wrapped around the gate dielectric layers 312B and the nanostructures 308B. In some embodiments, each of the gate structures 310A and 310B further includes interfacial layers formed between the gate dielectric layers 312A and the nanostructures 308A or between the gate dielectric layers 312B and the nanostructures 308B.

In some embodiments, the gate structures 310A are in direct contact with the top dielectric layers 320A, and the gate structures 310B are in direct contact with the top dielectric layers 320B. For example, the gate dielectric layers 312A of the gate structure 310A1 are in direct contact with the top dielectric layers 320A1 to 320A3, the gate dielectric layers 312A of the gate structure 310A2 are in direct contact with the top dielectric layers 320A3 to 320A5, and the gate dielectric layers 312A of the gate structure 310A3 are in direct contact with the top dielectric layers 320A5 to 320A7. For example, the gate dielectric layers 312B of the gate structure 310B1 are in direct contact with the top dielectric layers 320B1 to 320B3, the gate dielectric layers 312B of the gate structure 310B2 are in direct contact with the top dielectric layers 320B3 to 320B5, and the gate dielectric layers 312B of the gate structure 310B3 are in direct contact with the top dielectric layers 320B5 to 320B7.

In some embodiments, the gate isolation structures 316 extending in the Y-direction and the gate structures 310A and 310B extending in the Y-direction are arranged in the X-direction. For example, in the row RO1, the gate isolation structure 316-1, the gate structure 310A1, the gate isolation structure 316-4, the gate structure 310B1, and the gate isolation structure 316-7 are arranged sequentially in the X-direction. For example, in the row RO2, the gate isolation structure 316-2, the gate structure 310A2, the gate isolation structure 316-5, the gate structure 310B2, and the gate isolation structure 316-8 are arranged sequentially in the X-direction. For example, in the row RO3, the gate isolation structure 316-3, the gate structure 310A3, the gate isolation structure 316-6, the gate structure 310B3, and the gate isolation structure 316-9 are arranged sequentially in the X-direction.

In the same row (e.g., the row RO1, RO2, or RO3) of the semiconductor device 300, a gate pitch is a combination of a gate length of the gate structures 310A/310B in the X-direction and a space between one gate structure 310A/310B to one gate isolation structure 316 in the X-direction. Furthermore, the gate length of the gate structures 310A and 310B in the X-direction and a gate length of the gate isolation structures 316 in the X-direction are substantially the same. In some embodiments, the gate length of the gate structures 310A and 310B is in a range from about 5 nm to about 20 nm.

In some embodiments, the semiconductor device 300 further includes gate-end dielectric structures 322 disposed at ends of the gate structures 310A/310B and the gate isolation structures 316. More specifically, the gate-end dielectric structures 322 are formed on the opposite sides of the gate structures 310A/310B and the gate isolation structures 316 in the Y-direction, as shown in FIGS. 3, 4A and 4B. The gate-end dielectric structures 322 may include gate-end dielectric structures 322-1 to 322-4 extending lengthwise in the X-direction and spaced apart from each other in the Y-direction. In some embodiments, the circuit cells 302A1 and 302B1 are disposed between the gate-end dielectric structures 322-1 and 322-2 in the Y-direction, so that the circuit cells 302A1 and 302B1 are spaced apart from other circuit cells (not shown) in the Y-direction by the gate-end dielectric structure 322-1.

In some embodiments, the circuit cells 302A2 and 302B2 are disposed between the gate-end dielectric structures 322-2 and 322-3 in the Y-direction, so that the circuit cells 302A2 and 302B2 are spaced apart from the circuit cells 302A1 and 302B1 in the Y-direction by the gate-end dielectric structure 322-2. That is, the gate structures 310A2 and 310B2 and the gate isolation structures 316-2, 316-5, and 316-8 are spaced apart from the gate structures 310A1 and 310B1 and the gate isolation structures 316-1, 316-4, and 316-7 by the gate-end dielectric structure 322-2. In these embodiments, in the Y-direction, the gate-end dielectric structure 322-2 is disposed between and spaces apart the active regions 304A2 and 304A3, and is disposed between and spaces apart the active regions 304B2 and 304B3.

In some embodiments, the circuit cells 302A3 and 302B3 are disposed between the gate-end dielectric structures 322-3 and 322-4 in the Y-direction, so that the circuit cells 302A3 and 302B3 are spaced apart from the circuit cells 302A2 and 302B2 in the Y-direction by the gate-end dielectric structure 322-3. That is, the gate structures 310A3 and 310B3 and the gate isolation structures 316-3, 316-6, and 316-9 are spaced apart from the gate structures 310A2 and 310B2 and the gate isolation structures 316-2, 316-5, and 316-8 by the gate-end dielectric structure 322-3. In these embodiments, in the Y-direction, the gate-end dielectric structure 322-3 is disposed between and spaces apart the active regions 304A4 and 304A5, and is disposed between and spaces apart the active regions 304B4 and 304B5. Moreover, the circuit cells 302A3 and 302B3 may be spaced apart from other circuit cells (not shown) in the Y-direction by the gate-end dielectric structure 322-4.

In some embodiments, the gate-end dielectric structures 322 extend vertically into the isolation structures 318. More specifically, the gate-end dielectric structures 322 extend through the top dielectric layers 320 and extend into the isolation structures 318 in the Z-direction, as shown in FIGS. 4A and 4B. For example, the gate-end dielectric structure 322-1 extends through the top dielectric layers 320A1 and 320B1, and extends into the isolation structures 318A1 and 318B1. That is, portions of the gate-end dielectric structure 322-1 extend into the isolation structures 318A1 and 318B1, and the bottom surface of the gate-end dielectric structure 322-1 is lower than the bottom surfaces of the gate structures 310A1 and 310B1. For example, the gate-end dielectric structure 322-2 extends through the top dielectric layers 320A3 and 320B3, and extends into the isolation structures 318A3 and 318B3. That is, portions of the gate-end dielectric structure 322-2 extend into the isolation structures 318A3 and 318B3, and the bottom surface of the gate-end dielectric structure 322-2 is lower than the bottom surfaces of the gate structures 310A1, 310A2, 310B1, and 310B2.

For example, the gate-end dielectric structure 322-3 extends through the top dielectric layers 320A5 and 320B5, and extends into the isolation structures 318A5 and 318B5. That is, portions of the gate-end dielectric structure 322-3 extend into the isolation structures 318A5 and 318B5, and the bottom surface of the gate-end dielectric structure 322-3 is lower than the bottom surfaces of the gate structures 310A2, 310A3, 310B2, and 310B3. For example, the gate-end dielectric structure 322-4 extends through the top dielectric layers 320A7 and 320B7, and extends into the isolation structures 318A7 and 318B7. That is, portions of the gate-end dielectric structure 322-4 extend into the isolation structures 318A7 and 318B7, and the bottom surface of the gate-end dielectric structure 322-4 is lower than the bottom surfaces of the gate structures 310A3 and 310B3.

In some embodiments, the semiconductor device 300 further includes gate spacers 324 that are similar to the gate spacers 212 discussed above. More specifically, the gate spacers 324 are formed on sidewalls of the gate structures 310A and 310B and on sidewalls of the gate isolation structures 316, and over the nanostructures 308A and 308B, as shown in FIGS. 3, 4C and 4D. The gate spacers 324 may include multiple dielectric materials. In some embodiments, the gate spacers 324 may include a single layer or a multi-layer structure.

In some embodiments, the semiconductor device 300 further includes inner spacers 326 formed on sidewalls of the gate structures 310A and 310B and on sidewalls of the gate isolation structures 316, and below the topmost nanostructures 308A or 308B, as shown in FIGS. 4C and 4D. Furthermore, the inner spacers 326 are laterally formed between the source/drain features 328N (or 328P) and the gate structures 310A (or 310B) and between the source/drain features 328N (or 328P) and the gate isolation structures 316. The inner spacers 326 are also vertically formed between adjacent nanostructures 308A or 308B and between the bottommost nanostructures 308A or 308B and the substrate 301. The inner spacers 326 may include a dielectric material having higher k value than the gate spacers 324.

In some embodiments, the gate spacers 324 have a thickness in the X-direction in a range from about 3 nm to about 12 nm, and the inner spacers 326 have a thickness in the X-direction in a range from about 2 nm to about 10 nm. In some embodiments, for the gate structures 310A, a length of the outer gates formed between the gate spacers 324 in the X-direction is in a range from about 5 nm to about 20 nm, and a length of the inner gates formed between the inner spacers 326 in the X-direction is in a range from about 5 nm to about 20 nm. In some embodiments, for the gate structures 310B, a length of the outer gates formed between the gate spacers 324 in the X-direction is in a range from about 5 nm to about 20 nm, and a length of the inner gates formed between the inner spacers 326 in the X-direction is in a range from about 5 nm to about 20 nm.

In some embodiments, the semiconductor device 300 may further include source/drain features 328N and source/drain features 328P over the substrate 301 and in the source/drain regions of the active regions 304A and 304B. More specifically, the source/drain features 328N and the source/drain features 328P are respectively disposed between one respective gate structure 310A or 310B and one respective gate isolation structure 316. As shown in FIG. 4C, the source/drain features 328N are disposed on opposite sides of the respective gate structure 310A in the X-direction and on opposite sides of the respective gate structure 310B in the X-direction to form n-type transistors. Similarly, as shown in FIG. 4D, the source/drain features 328P are disposed on opposite sides of the respective gate structure 310A in the X-direction and on opposite sides of the respective gate structure 310B in the X-direction to form p-type transistors.

In the column CO1, the nanostructures 308A extend in the X-direction to connect one source/drain feature 328N/328P to another source/drain feature 328N/328P. Similarly, in the column CO2, the nanostructures 308B extend in the X-direction to connect one source/drain feature 328N/328P to another source/drain feature 328N/328P. More specifically, the source/drain features 328N and the source/drain features 328P are disposed on opposite sides of the respective nanostructures 308A/308B in the X-direction. Therefore, the source/drain features 328N/328P are attached and electrically connected to the nanostructures 308A/308B in the X-direction. The source/drain features 328N/328P may also be referred to as source/drain, or source/drain regions. In some embodiments, source/drain feature(s) may refer to a source or a drain, individually or collectively dependent upon the context.

The source/drain features 328N and 328P may be formed by using epitaxial growth. In some embodiments, the source/drain features 328N may include epitaxially-grown material selected from a group consisting of SiP, SiC, SiPC, SiAs, Si, or a combination thereof. In some embodiments, the epitaxially-grown material of the source/drain features 328N may be doped with n-type dopants (e.g., P, As, other n-type dopant, or combinations thereof) having a doping concentration in a range from about 2×10¹⁹/cm³ to 3×10²¹/cm³. In some embodiments, the source/drain features 328N for n-type transistors may be respectively referred to as n-type source/drain features.

In some embodiments, the source/drain features 328P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 328P may be doped with p-type dopants (such as B, In, other p-type dopant, or combinations thereof) having a doping concentration in a range from about 1×10¹⁹/cm³ to 6×10²⁰/cm³. In some embodiments, the source/drain features 328P for p-type transistors may be respectively referred to as p-type source/drain features.

In some embodiments, the semiconductor device 300 further includes silicide layers 330 over and in contact with the source/drain features 328N and 328P, as shown in FIGS. 4C and 4D. In some embodiment, each of the silicide layers 330 is disposed between the adjacent one gate structure 310A/310B and one gate isolation structure 316 in the X-direction. The silicide layers 330 may include TiSi, NiSi, WSi, NiPtSi, NiPtGeSi, NiGeSi, YbSi, PtSi, IrSi, ErSi, CoSi, or other suitable compounds. In some embodiments, the silicide layers 330 over the source/drain features 328N and the silicide layers 330 over the source/drain features 328P have different material. For example, the silicide layers 330 over the source/drain features 328N may include TiSi and the silicide layers 330 over the source/drain features 328P may include silicide material selected from a group consist of PtSi, NiSi, CoSi, or MoSi.

In some embodiments, the semiconductor device 300 includes source/drain contacts 332A1 to 332A7 (which may be collectively referred to as source/drain contacts 332A) for the transistors of the circuit cells 302A1 to 302A3, and includes source/drain contacts 332B1 to 332B7 (which may be collectively referred to as source/drain contacts 332B) for the transistors of the circuit cells 302B1 to 302B3, as shown in FIGS. 3, 4C, and 4D. The source/drain contacts 332A and 332B are disposed over and in contact with the silicide layers 330, and electrically connected to the source/drain features 328N and 328P through the silicide layers 330. The source/drain contacts 332A and 332B extend lengthwise the Y-direction. As shown in FIG. 3, in the top view, the source/drain contacts 332A are formed on the opposite sides of the gate structures 310A1 to 310A3, and the source/drain contacts 332B are formed on the opposite sides of the gate structures 310B1 to 310B3.

In some embodiments, the source/drain contacts 332A and 332B are self-aligned source/drain contacts. This means that the source/drain contacts 332A and 332B are formed by using the gate spacers 324 as masks. Therefore, the source/drain contacts 332A and 332B are in direct contact with the gate spacers 324, as shown in FIGS. 4C and 4D. In some embodiments, the gate spacers 324 are trimmed due to the gate spacers 324 serving as the mask for forming the source/drain contacts 332A and 332B. Therefore, the thickness of the gate spacers 324 in the X-direction may be less than the thickness of the inner spacers 326 in the X-direction. In some embodiments, the top surfaces of the source/drain contacts 332A and 332B are substantially level with the top surfaces of the gate structures 310A and 310B and the gate spacers 324 when the source/drain contacts 332A and 332B are self-aligned source/drain contacts.

In some embodiments, the source/drain contacts 332A and 332B are non-self-aligned source/drain contacts. This means that the source/drain contacts 332A and 332B are not formed by using the gate spacers 324 as masks. In these embodiments, the source/drain contacts 332A and 332B may be separated from the gate spacers 324 by a dielectric layer (e.g., an inter-layer dielectric (ILD) layer 336). As such, the contact-to-gate parasitic capacitance is reduced. Furthermore, in these embodiments, the thickness of the gate spacers 324 may be the same as or greater than the thickness of the inner spacers 326 in the X-direction.

In some embodiments, the source/drain contacts 332A2, 332A4, and 332A6 each is directly disposed over and electrically connected to one source/drain feature 328N and one source/drain feature 328P in the same circuit cell. In some embodiments, the source/drain contacts 332A1, 332A3, 332A5, 332A7 each is disposed over and electrically connected to two source/drain features 328N or 328P in two circuit cells in adjacent two rows of the semiconductor device 300. Referring to FIG. 3, the source/drain contact 332A1 is over and electrically connected to one source/drain feature 328N of the transistor constructed by the active region 304A1 and the gate structure 310A1. The source/drain contact 332A2 is over and electrically connected to another source/drain feature 328N of the transistor constructed by the active region 304A1 and the gate structure 310A1 and one source/drain feature 328P of the transistor constructed by the active region 304A2 and the gate structure 310A1. The source/drain contact 332A3 is over and electrically connected to another source/drain feature 328P of the transistor constructed by the active region 304A2 and the gate structure 310A1 and one source/drain feature 328P of the transistor constructed by the active region 304A3 and the gate structure 310A2.

The source/drain contact 332A4 is over and electrically connected to another source/drain feature 328P of the transistor constructed by the active region 304A3 and the gate structure 310A2 and one source/drain feature 328N of the transistor constructed by the active region 304A4 and the gate structure 310A2. The source/drain contact 332A5 is over and electrically connected to another source/drain feature 328N of the transistor constructed by the active region 304A4 and the gate structure 310A2 and one source/drain feature 328N of the transistor constructed by the active region 304A5 and the gate structure 310A3. The source/drain contact 332A6 is over and electrically connected to another source/drain feature 328N of the transistor constructed by the active region 304A5 and the gate structure 310A3 and one source/drain feature 328P of the transistor constructed by the active region 304A6 and the gate structure 310A3. The source/drain contact 332A7 is over and electrically connected to another source/drain feature 328P of the transistor constructed by the active region 304A6 and the gate structure 310A3.

In some embodiments, the source/drain contacts 332B2, 332B4, and 332B6 each is directly disposed over and electrically connected to one source/drain feature 328N and one source/drain feature 328P in the same circuit cell. In some embodiments, the source/drain contacts 332B1, 332B3, 332B5, 332B7 each is disposed over and electrically connected to two source/drain features 328N or 328P in two circuit cells in adjacent two rows of the semiconductor device 300. Referring to FIG. 3, the source/drain contact 332B1 is over and electrically connected to one source/drain feature 328N of the transistor constructed by the active region 304B1 and the gate structure 310B1. The source/drain contact 332B2 is over and electrically connected to another source/drain feature 328N of the transistor constructed by the active region 304B1 and the gate structure 310B1 and one source/drain feature 328P of the transistor constructed by the active region 304B2 and the gate structure 310B1. The source/drain contact 332B3 is over and electrically connected to another source/drain feature 328P of the transistor constructed by the active region 304B2 and the gate structure 310B1 and one source/drain feature 328P of the transistor constructed by the active region 304B3 and the gate structure 310B2.

The source/drain contact 332B4 is over and electrically connected to another source/drain feature 328P of the transistor constructed by the active region 304B3 and the gate structure 310B2 and one source/drain feature 328N of the transistor constructed by the active region 304B4 and the gate structure 310B2. The source/drain contact 332B5 is over and electrically connected to another source/drain feature 328N of the transistor constructed by the active region 304B4 and the gate structure 310B2 and one source/drain feature 328N of the transistor constructed by the active region 304B5 and the gate structure 310B3. The source/drain contact 332B6 is over and electrically connected to another source/drain feature 328N of the transistor constructed by the active region 304B5 and the gate structure 310B3 and one source/drain feature 328P of the transistor constructed by the active region 304B6 and the gate structure 310B3. The source/drain contact 332B7 is over and electrically connected to another source/drain feature 328P of the transistor constructed by the active region 304B6 and the gate structure 310B3.

In some embodiments, the source/drain contacts 332A1, 332A3, 332A5, 332A7, 332B1, 332B3, 332B5, and 332B7 each is also disposed over the gate-end dielectric structures 322, as shown in FIG. 3. For example, the source/drain contacts 332A1 and 332B1 extend in the Y-direction and overlap the gate-end dielectric structure 322-1, and the source/drain contacts 332A3 and 332B3 extend in the Y-direction and overlap the gate-end dielectric structure 322-2. For example, the source/drain contacts 332A5 and 332B5 extend in the Y-direction and overlap the gate-end dielectric structure 322-3, and the source/drain contacts 332A7 and 332B7 extend in the Y-direction and overlap the gate-end dielectric structures 322-4. In some embodiments, the source/drain contacts 332A1, 332A3, 332A5, 332A7, 332B1, 332B3, 332B5, and 332B7 are in contact with the gate-end dielectric structures 322.

Referring to FIGS. 4A to 4D, the semiconductor device 300 further includes a cap layer 334, the ILD layer 336, and an inter-metal dielectric (IMD) layer 338. The cap layer 334 is formed over the gate structures 310A and 310B for protecting the gate structures 310A and 310B. In some embodiments, the cap layer 334 includes a dielectric material such as silicon nitride (Si₃N₄). The ILD layer 336 is disposed over the substrate 301, the isolation structures 318, the top dielectric layers 320, the gate structures 310A and 310B, the gate isolation structures 316, the gate-end dielectric structures 322, the source/drain contacts 332A and 332B, and the cap layer 334. The IMD layer 338 is disposed over the ILD layer 336.

The ILD layer 336 and the IMD layer 338 may include a dielectric material including, for example, SiO₂, SiN, SiON, TEOS-formed oxide, phosphosilicate glass (PSG), borophosphosilicate glass (BPSG), low-k dielectric material, other suitable dielectric material, or combinations thereof. Exemplary low-k dielectric materials include fluoride-doped silica glass (FSG), carbon doped silicon oxide, xerogel, aerogel, amorphous fluorinated carbon, parylene, BCB-based dielectric material, polyimide, other low-k dielectric material, or combinations thereof. The ILD layer 336 and the IMD layer 338 may include a multilayer structure having multiple dielectric materials.

In some embodiments, the semiconductor device 300 further includes gate vias VG, vias VD, and metal layers M1. The gate vias VG and vias VD are disposed in the ILD layer 336, and the metal layers M1 are disposed in the IMD layer 338. The metal layers M1 are disposed over the gate structures 310A/310B and the source/drain contacts 332A/332B. The gate vias VG are over and in contact with the gate structures 310A/310B and electrically connect the gate structures 310A/310B to respective metal layers M1. The vias VD are over and in contact with the source/drain contacts 332A/332B and electrically connect the source/drain contacts 332A/332B to respective metal layers M1. The materials of the gate vias VG, the vias VD, and the metal layers M1 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

As shown in FIGS. 3 and 4A to 4D, the metal layers M1 extend in the X-direction and further include metal layers MN, VM1, VM2, VM3, and VM4. The metal layers MN are disposed within the cell boundaries (e.g., the circuit cells 302A1 to 302A3 and 302B1 to 302B3) in the top view, as shown in FIG. 3. The metal layers VM1, VM2, VM3, and VM4 are disposed overlap the gate-end dielectric structures 322 in the top view, as shown in FIG. 3. In some embodiments, a width of the metal layers VM1, VM2, VM3, and VM4 is greater than a width of the metal layers MN in the Y-direction.

The metal layers M1 are respectively connected to respective gate structures 310A/310B and respective source/drain contacts 332A/332B through respective gate vias VG and respective vias VD. In some embodiments, the gate vias VG, the vias VD, and the metal layers M1 are used to construct connections of the transistors in the circuit cells. In some embodiments, the vias VD and metal layers M1 are connected to power sources or voltage sources (not shown) to provide voltage (VDD or VSS) to the transistors in the circuit cells. In the present embodiment, the metal layers VM1 and VM3 are connected to a VSS power source (not shown) and the metal layers VM2 and VM4 are connected to a VDD power source (not shown).

In some embodiments, the vias VD electrically connected to the source/drain contacts 332A/332B have larger sizes than the vias VG electrically connected the gate structures 310A/310B, as shown in FIG. 3. In some embodiments, the vias VD may include vias VD_A that are electrically connected to the metal layers VM2 and VM3, vias VD_B that are electrically connected to the metal layers VM1 and VM4, and vias VD_C that are electrically connected to the metal layers MN. In some embodiments, the vias VD may have different sizes. For example, the vias VD_A may have larger sizes than the vias VD_B and VD_C. Alternatively, the vias VD_A and VD_B may have larger sizes than the vias VD_C. Therefore, due to small resistances of larger size vias VD_A and/or VD_B, the transistors in the circuit cells 302A1 to 302A3 and 302B1 to 302B3 may be provided with voltage (or power) with low voltage drop, thereby improving the performance of the semiconductor device 300.

In some embodiments, the vias VD may have different length-to-width ratios. The length-to-width ratio described herein is the ratio of the length of the via to the width of the via, wherein the length of the via is along Y-direction, and the width of the via is along X-direction. For example, for the vias VD_A, the length-to-width ratio may be equal to or greater than 1.5, and for the vias VD_B and VD_C, the length-to-width ratio may be less than 1.5. Alternatively, for the vias VD_A and VD_B, the length-to-width ratio may be equal to or greater than 1.5, and for the vias VD_C, the length-to-width ratio may be less than 1.5. In some embodiments, the vias VD_A electrically connected to the metal layers VM2 are partially overlapped with the gate-end dielectric structure 322-2, and the vias VD_A electrically connected to the metal layers VM3 are partially overlapped with the gate-end dielectric structure 322-3, as shown in FIG. 3. In further embodiments, the vias VD_B electrically connected to the metal layers VM1 are partially overlapped with the gate-end dielectric structure 322-1, and the vias VD_B electrically connected to the metal layers VM4 are partially overlapped with the gate-end dielectric structure 322-4, as shown in FIG. 3.

In some embodiments, the semiconductor device 300 further includes bottom isolation layers 333 disposed under the source/drain features 328N and 328P and over the substrate 301, as shown in FIGS. 4C and 4D. In some embodiment, the bottom isolation layers 333 are in partial contact with the sidewalls of the inner spacers 326, and the bottom surfaces of the bottom isolation layers 333 are lower than the topmost surfaces of the base fins (e.g., the base fins 306A and 306B), as shown in FIGS. 4C and 4D. In some embodiments, the bottom isolation layers 333 may include dielectric materials. It should be noted that the source/drain features 328N and 328P are separated from the substrate 301 by the bottom isolation layers 333. As such, it prevents the leakage current of the resultant transistors flowing from one source/drain feature 328N/328P to another source/drain feature 328N/328P through the substrate 301, thereby improving performances of the resultant transistors.

As described above, the ratio of spacing S5 to spacing S4 and the ratio of spacing S6 to spacing S4 are in a range from about 1.1 to about 2, and the spacing S4 may be substantially the same as the spacing S1. As described above, the width W1 is greater than the width W3, and the width W2 is greater than the width W4. Since the circuit cells 302A1 to 302A3 and the circuit cells 302B1 to 302B3 have the same dimension in the Y-direction, the differences between the width W1 and the width W3 and between the width W2 and the width W4 are distributed to the spacings S5 and S6. The difference between the spacing S4 and the spacing S5/S6 may induce the loading effect, which can be used to achieve the different thicknesses H4, H5, and H6 of the top dielectric layers 320A1 to 320A7.

As described above, the active regions 304B in different wells are separated by the spacing S4, and the active regions 304B in the same n-type well and the same p-type well are separated by the spacing S5 and S6, respectively. That is, portions of the gate structures 310B between the active regions 304B in different wells has a smaller width in the Y-direction (equal to the spacing S4). Such smaller width of the gate structures 310B may reduce the gate-to-contact parasitic capacitance. Furthermore, the larger spacings S5 and S6 ensure that there is enough space between the gate structures 310B in the Y-direction, such that the gate-end dielectric structures 322 have a larger process window that can be formed between the gate structures 310B, and the process margin for preventing the source/drain features bridging is also improved.

On the other hand, if the ratio of spacing S5 or spacing S6 to spacing S4 is too small (the ratio is less than 1.1), then the spacing S5 or the spacing S6 is too small and/or the spacing S4 is too large, thereby the gate-to-contact parasitic capacitance cannot be significantly reduced, and the induced loading effect may not achieve the desired thicknesses H4, H5, and H6. If the ratio of spacing S5 or spacing S6 to spacing S4 is too large (the ratio is greater than 2), the spacing S5 or the spacing S6 is too large and/or the spacing S4 is too small, thereby the size of the circuit cells is increased to impact the device density and/or the process window for the gate structures 310A and 310B is impacted.

As described above, the top dielectric layers 320A and 320B have different thicknesses. Therefore, portions of the gate structures 310A over the top dielectric layers 320A and portions of the gate structures 310B over the top dielectric layers 320B also have different heights. For the sake of simplicity and clarity, take the gate structure 310A2 shown in FIG. 6A for an example: a portion of the gate structure 310A2 over the top dielectric layer 320A4 and lower than the top surfaces of the base fins 306A1 to 306A6 has the height R1; a portion of the gate structure 310A2 over the top dielectric layer 320A3 and lower than the top surfaces of the base fins 306A1 to 306A6 has the height R2; and a portion of the gate structure 310A2 over the top dielectric layer 320A5 and lower than the top surfaces of the base fins 306A1 to 306A6 has the height R3. Further, take the gate structure 310B2 shown in FIG. 6B for an example: a portion of the gate structure 310B2 over the top dielectric layer 320B4 and lower than the top surfaces of the base fins 306B1 to 306B6 has the height R4; a portion of the gate structure 310B2 over the top dielectric layer 320B3 and lower than the top surfaces of the base fins 306B1 to 306B6 has the height R5; and a portion of the gate structure 310B2 over the top dielectric layer 320B5 and lower than the top surfaces of the base fins 306B1 to 306B6 has the height R6.

As described above, the ratio of thickness H5 to thickness H4 and the ratio of thickness H6 to thickness H4 are in a range from about 1.1 to about 4, and the ratio of height R4 to height R5 and the ratio of height R4 to height R6 are in a range from about 1.1 to about 3. That is, the larger height is due to the smaller thickness, and vice versa. Take the gate structure 310B2 shown in FIG. 6B for the example, the greater thickness H5 and the smaller height R5 reduce the contact area between the base fin 306B3 and the gate structure 310B2, and the greater thickness H6 and the smaller height R6 reduce the contact area between the base fin 306B4 and the gate structure 310B2. As a result, the parasitic capacitance induced by the base fins (e.g., the base fins 306B3 and 306B4) and the gate structure (e.g., the gate structure 310B2) can be suppressed. Moreover, the smaller thickness H4 and the greater height R4 between two adjacent bas fins (e.g., the base fins 306B3 and 306B4) sharing the same gate structure (e.g., the gate structure 310B2) can ensure that there is enough process window in channel release process (for removing sacrificial layers).

Since the devices (e.g., circuit cells 302A1 to 302A3) having smaller channel widths (e.g., the widths W3 and W4) are more sensitive to parasitic capacitance, the greater thicknesses H5, H6 and the smaller heights R5, R6 are applied to the circuit cells 302A1 to 302A3. On the other hand, the devices (e.g., circuit cells 302B1 to 302B3) having wider channel widths (e.g., the widths W1 and W2) are more tolerable to the parasitic capacitance. Therefore, the smaller thicknesses H1, H2, H3 and the greater heights R1, R2, R3 are applied to the circuit cells 302B1 to 302B3. For example, as described above, the ratio of thickness H5 to thickness H2 and the ratio of thickness H6 to thickness H3 may be in a range from about 1.1 to about 4; the thickness H4 may be substantially the same as or greater than the thickness H1; the ratio of height R2 to height R5 and the ratio of height R3 to height R6 may be in a range from about 1.1 to about 3; and the height R1 may be substantially the same as or greater than the height R4. Since the circuit cells 302B1 to 302B3 have smaller thicknesses H1, H2, H3 and greater heights R1, R2, R3, the process window of the channel release process can be improved to ensure that the wider sacrificial layers can be removed.

Furthermore, the top dielectric layers 320 include the nitrogen content material, which can protect the isolation structures 318 and the top dielectric layers 320 during the channel release process. Therefore, the heights of the isolation structures 318 and the top dielectric layers 320 will be minimal reduced (or substantially no reduced) during the channel release process, and thus the sidewalls of the bas fins 306A1 to 306A6 and 306B1 to 306B6 will not be exposed more during the channel release process. Accordingly, the isolation structures 318 and the top dielectric layers 320 can maintain the original design heights and suppress the increase of parasitic capacitance. As a result, the process margin and the device performance can be improved at the same time.

On the other hand, if the ratio of thickness H5 or H6 to thickness H4 is too small (the ratio is less than 1.1, and thus the ratio of height R4 to height R5 or height R6 is less than 1.1), the thickness H5 or H6 is too small and/or the thickness H4 is too large, thereby the parasitic capacitance cannot be significantly reduced and/or process window in channel release process is impacted. If the ratio of thickness H5 or thickness H6 to thickness H4 is too large (the ratio is greater than 4, and thus the ratio of height R4 to height R5 or R6 is greater than 3), the thickness H5 or H6 is too large and/or the thickness H4 is too small, thereby the performance of the transistor is impacted.

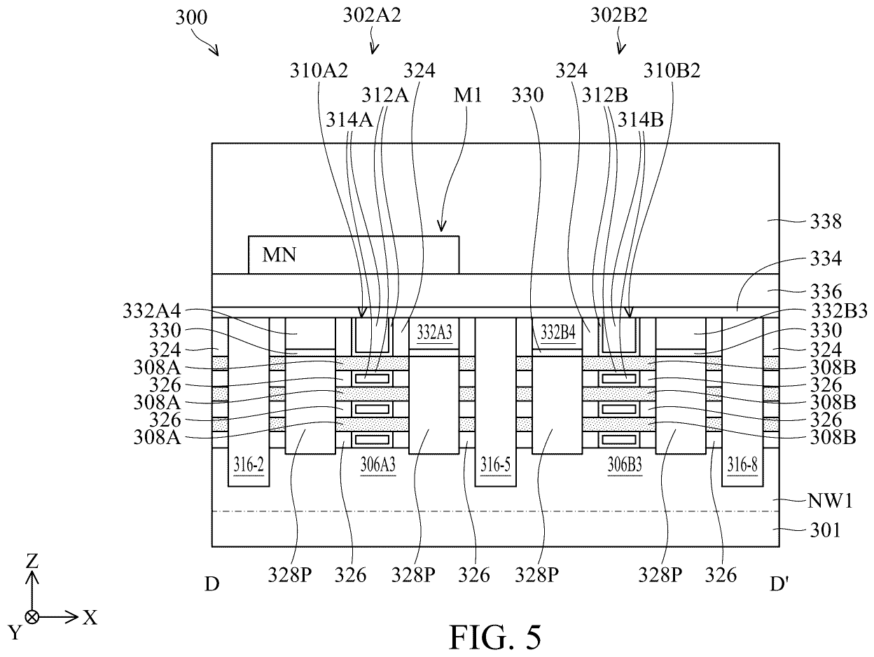

FIG. 5 illustrates an X-Z cross-sectional view of the semiconductor device 300 along a line D-D′ of FIG. 3, in accordance with some alternative embodiments. The semiconductor device 300 shown in FIG. 5 is similar to the semiconductor device 300 shown in FIG. 4D described above, except that the semiconductor device 300 shown in FIG. 5 omits the bottom isolation layers 333 under the source/drain features 328P. In some embodiments, the bottom isolation layers 333 are still disposed under the source/drain features 328N (see FIG. 4C), and the source/drain features 328P are disposed over and in direct contact with the substrate 301 without the bottom isolation layers 333 (see FIG. 5). Therefore, each of the source/drain features 328P has a larger volume than the source/drain features 328N to enhance the strain for nanostructures 308A and 308B in the p-type transistors, thereby improving the performance of the p-type transistors in the semiconductor device 300.

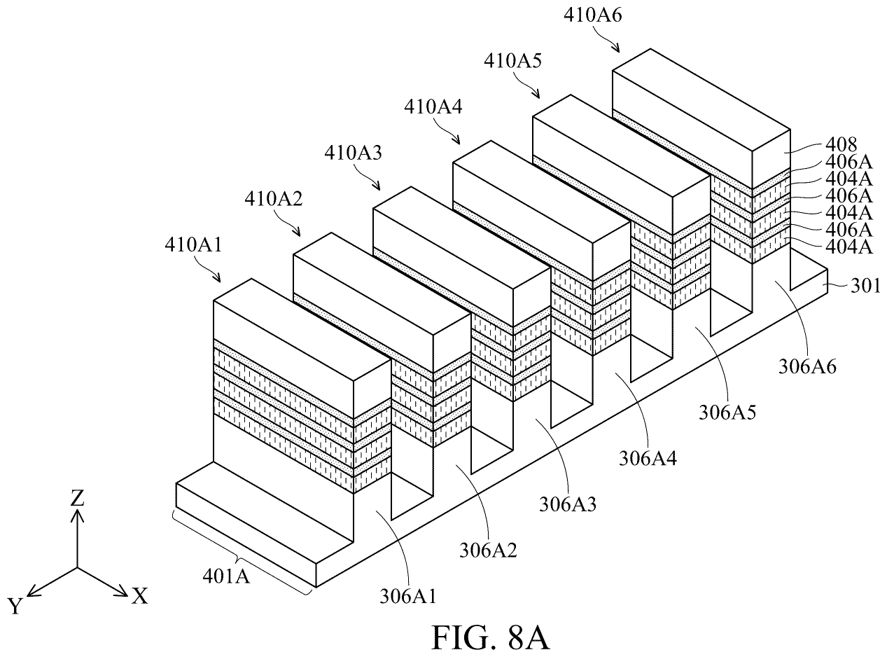

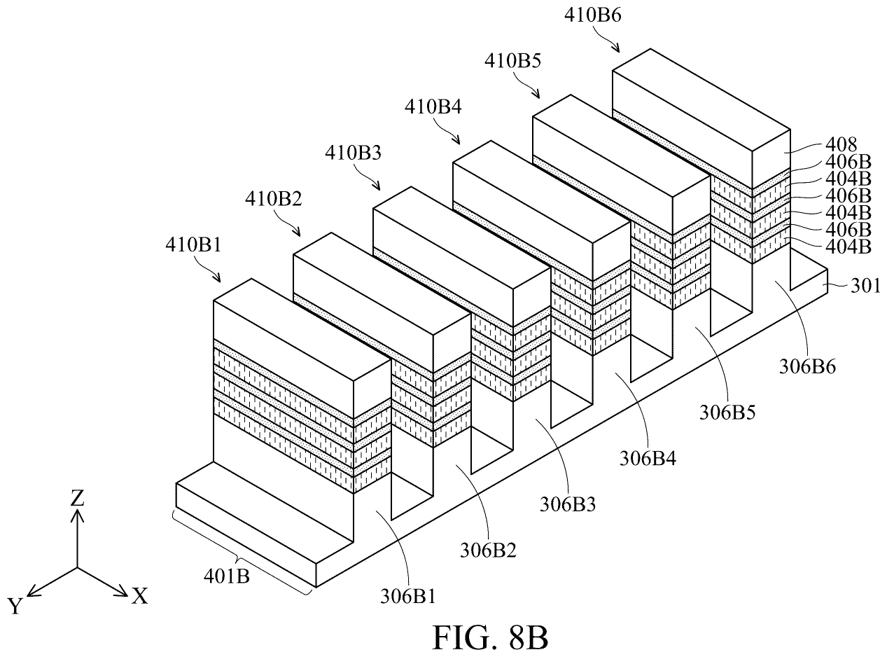

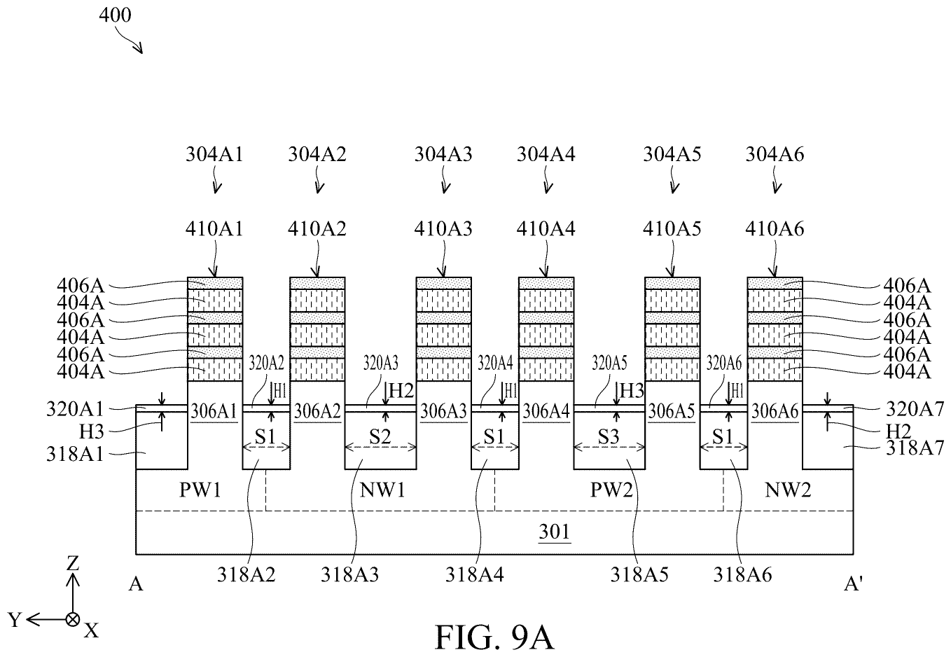

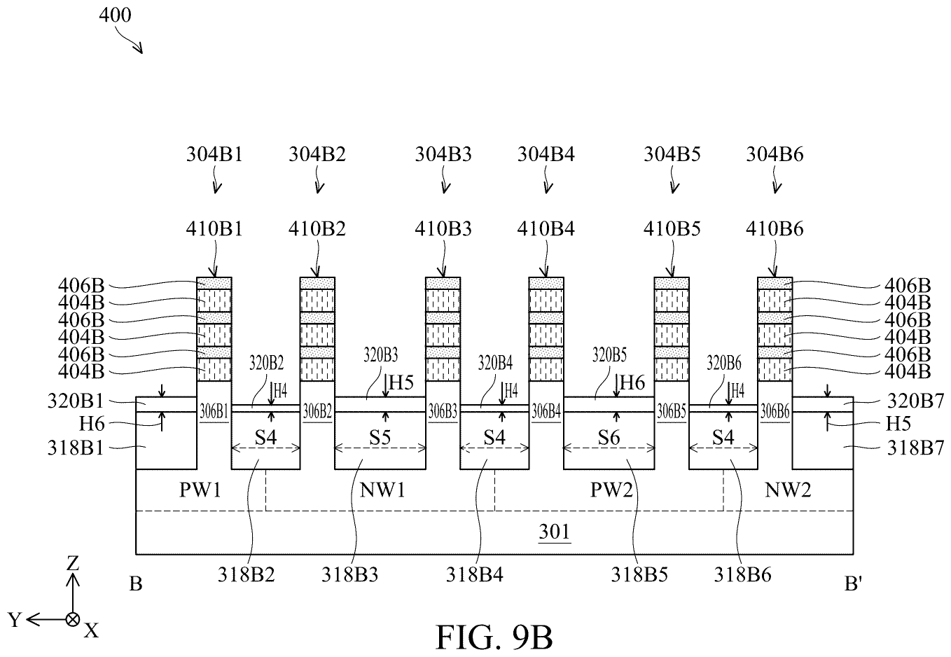

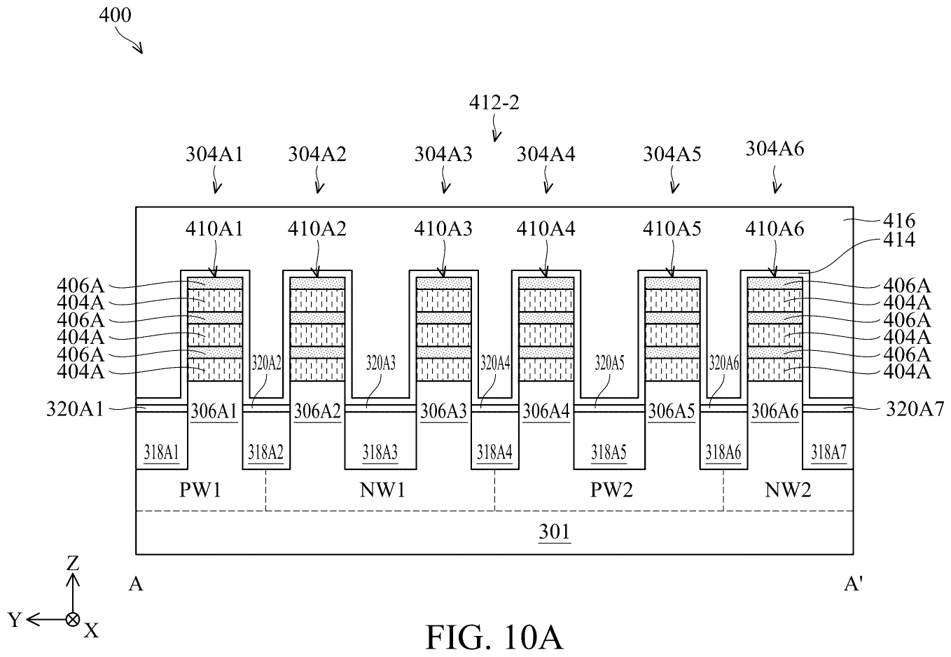

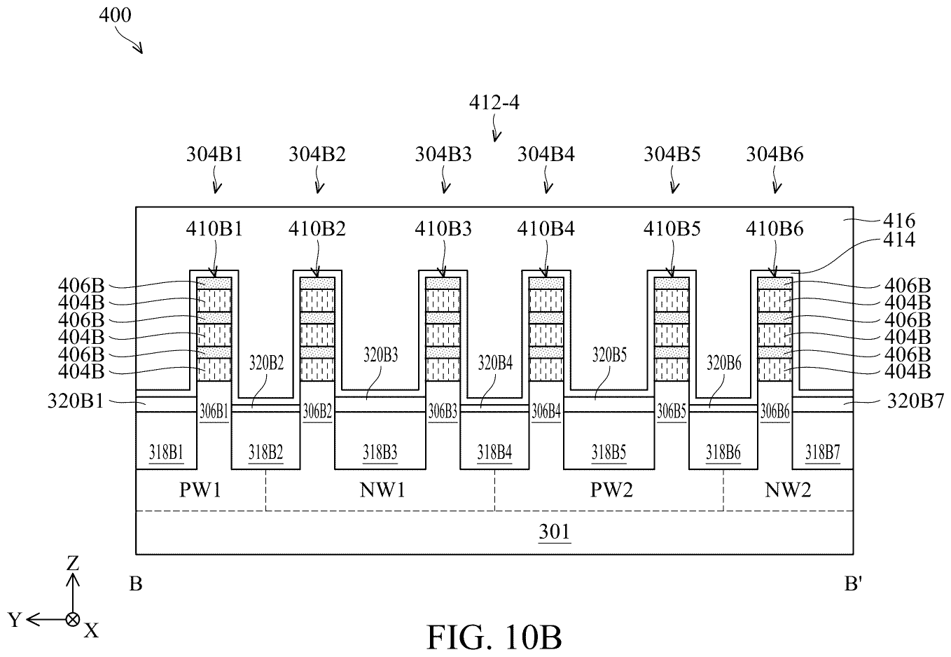

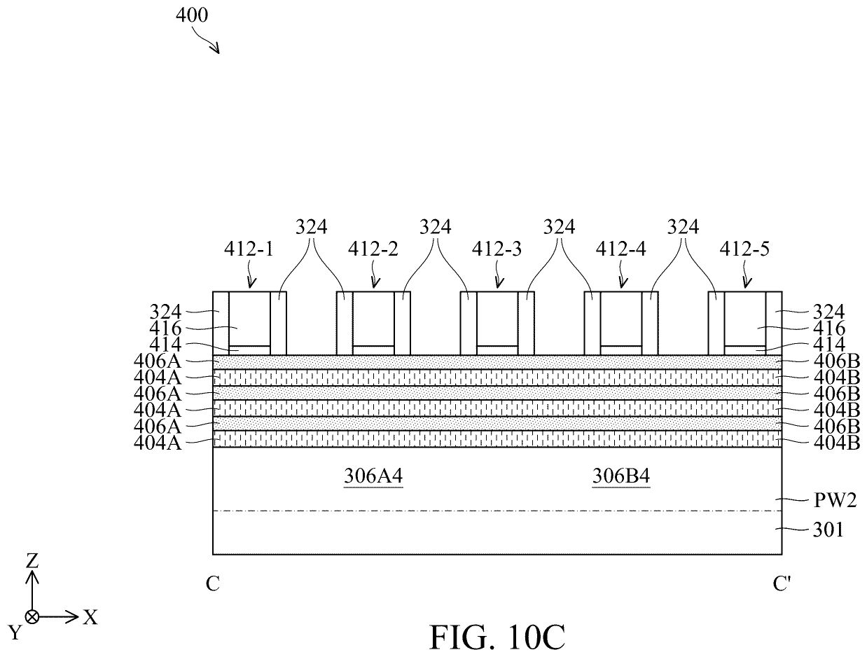

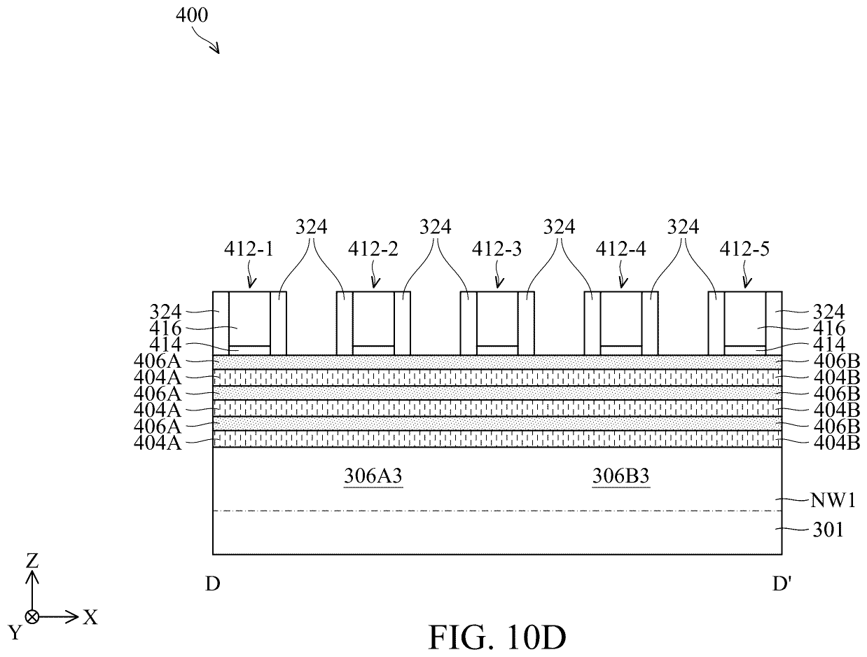

FIGS. 7, 8A, and 8B are perspective view of a workpiece 400 at various fabrication stages for the semiconductor device 300, in accordance with some embodiments. FIGS. 9A, 10A, 11A, 12A, 13A, and 14A are cross-sectional views of the workpiece 400 at various fabrication stages along line A-A′ of FIGS. 8A and 8B, in accordance with some embodiments. FIGS. 9B, 10B, 11B, 12B, 13B, and 14B are cross-sectional views of the workpiece 400 at various fabrication stages along line B-B′ of FIGS. 8A and 8B, in accordance with some embodiments. FIGS. 10C, 11C, 12C, 13C, and 14C are cross-sectional views of the workpiece 400 at various fabrication stages along line C-C′ of FIGS. 8A and 8B, in accordance with some embodiments. FIGS. 10D, 11D, 12D, 13D, and 14D are cross-sectional views of the workpiece 400 at various fabrication stages along line D-D′ of FIGS. 8A and 8B, in accordance with some embodiments.

Referring to FIG. 7, a stack 402 is formed over the substrate 301. In some embodiments, the substrate 301 may include one or more well regions, such as n-type wells (e.g., the n-type wells NW1 and NW2 discussed above) doped with an n-type dopant (e.g., P or As) or p-type wells (e.g., the p-type wells PW1 and PW2 discussed above) doped with a p-type dopant (e.g., B, In). In some embodiments, an ion implantation process, a thermal diffusion process, and/or other suitable doping process can be performed to form the n-type wells and the p-type wells.

In some embodiments, the stack 402 includes semiconductor layers 404 and semiconductor layers 406 that are stacked in an alternating manner in the Z-direction. The semiconductor layers 404 and the semiconductor layers 406 may have different semiconductor compositions. In some embodiments, semiconductor layers 404 are formed of SiGe and the semiconductor layers 406 are formed of Si. In these embodiments, the additional germanium content in the semiconductor layers 404 allow selective removal or recess of the semiconductor layers 404 without substantial damage to the semiconductor layers 406, so that the semiconductor layers 404 are also referred to as sacrificial layers.

In some embodiments, the semiconductor layers 404 and 406 are epitaxially grown over or on the substrate 301 using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 404 and the semiconductor layers 406 are deposited alternatingly, one-after-another, to form the stack 402.

It should be noted that three layers of the semiconductor layers 404 and three layers of the semiconductor layers 406 are alternately and vertically arranged (or stacked) as shown in FIG. 7, which are for illustrative purposes only and not intended to be limiting beyond what is specifically recited in the claims. The number of layers depends on the desired number of channels members for the semiconductor device. In some embodiments, there may be from 2 to 10 semiconductor layers 404 alternating with 2 to 10 semiconductor layers 406 in the stack 402.

For patterning purposes, the workpiece 400 may also include a hard mask layer 408 over the stack 402. The hard mask layer 408 may be a single layer structure or a multi-layer structure. In some embodiments, the hard mask layer 408 is a single layer structure and includes a silicon germanium layer. In some embodiments, the hard mask layer 408 is a multi-layer structure and includes a silicon nitride layer and a silicon oxide layer over the silicon nitride layer.

Referring to FIGS. 8A and 8B, FIG. 8A illustrates a region 401A of the workpiece 400 and FIG. 8B illustrates a region 401B of the workpiece 400, in accordance with some embodiments. The region 401A may be used to fabricate the column CO1 (i.e., the circuit cells 302A1 to 302A3) of the semiconductor device 300, and the region 401B may be used to fabricate the column CO2 (i.e., the circuit cells 302B1 to 302B3) of the semiconductor device 300.

In some embodiments, after the formation of the stack 402, the active regions 304A1 to 304A6 are defined on the region 401A by patterning the stack 402 to form fins 410A1 to 410A6 (may be collectively referred to as fins 410A) over the substrate 301. Similarly, the active regions 304B1 to 304B6 are defined on the region 401B by patterning the stack 402 to form fins 410B1 to 410B6 (may be collectively referred to as fins 410B) over the substrate 301. Each of the fins 410A1 to 410A6 may include a stack portion including semiconductor layers 404A and 406A alternately stacked in the Z-direction and the base fin discussed above (i.e., the base fins 306A1 to 306A6) below the stack portion, as shown in FIG. 8A. Each of the fins 410B1 to 410B6 may include a stack portion including semiconductor layers 404B and 406B alternately stacked in the Z-direction and the base fin discussed above (i.e., the base fins 306B1 to 306B6) below the stack portion, as shown in FIG. 8B. The semiconductor layers 404A and 404B are formed from the semiconductor layers 404, and the semiconductor layers 406A and 406B are formed from the semiconductor layers 406.

As described above, the active regions 304A1, 304A4, and 304A5 (having the width W1) are wider than the active regions 304B1, 304B4, and 304B5 (having the width W3), and the active regions 304A2, 304A3, and 304A6 (having the width W2) are wider than the active regions 304B2, 304B3, and 304B6 (having the width W4). Therefore, the fins 410A1, 410A4, and 410A5 are wider than the fins 410B1, 410B4, and 410B5 in the Y-direction, and the fins 410A2, 410A3, and 410A6 are wider than the fins 410B2, 410B3, and 410B6 in the Y-direction. The widths W1, W2, W3, and W4 are defined after the formation of the fins 410A and 410B. Furthermore, the spacings S1, S2, and S3 discussed above between the active regions 304A1 to 304A6 and the spacings S4, S5, and S6 discussed above between the active regions 304B1 to 304B6 are also defined after the formation of the fins 410A and 410B.

Referring to FIGS. 9A and 9B, after the definition of the active regions 304A and 304B and the formation of the fins 410A and 410B, the isolation structures 318A (including the isolation structures 318A1 to 318A7) and 318B (including the isolation structures 318B1 to 318B7) are formed over the substrate 301. The isolation structures 318A are also formed between the active regions 304A, and the isolation structures 318B are also formed between the active regions 304B. In some embodiments, a dielectric material for the isolation structures 318A and 318B is first deposited to cover the fins 410A and 410B and the substrate 301. In some embodiments, the dielectric material is formed to be wrapped around the fins 410A and 410B. In some embodiments, the dielectric material is deposited using a deposition process, such as CVD, subatmospheric CVD (SACVD), flowable CVD (FCVD), ALD, spin-on coating, and/or other suitable process.

The deposited dielectric material is then thinned and planarized, for example by a chemical mechanical polishing (CMP) process, until the hard mask layer 408 is removed. The planarized dielectric material is further recessed by a dry etching process, a wet etching process, and/or a combination thereof to form the isolation structures 318A and 318B. In some embodiments, before the formation of the isolation structures 318A and 318B, liner layers may be conformally deposited over the substrate 301 using a deposition process, such as CVD, ALD, PECVD, high-density plasma CVD (HDPCVD), MOCVD, RPCVD, LPCVD, atomic layer CVD (ALCVD), atmospheric pressure CVD (APCVD), FCVD, or combinations thereof.

Still referring to FIGS. 9A and 9B, after the formation of the isolation structures 318A and 318B, the top dielectric layers 320A (including the top dielectric layers 320A1 to 320A7) and 320B (including the top dielectric layers 320B1 to 320B7) are formed over the isolation structures 318A and 318B. The top dielectric layers 320A are also formed between the active regions 304A, and the top dielectric layers 320B are also formed between the active regions 304B. As described above, the top dielectric layers 320A and 320B have different thicknesses H1, H2, H3, H4, H5, and H6. In some embodiments, one or more deposition, photolithography, and etching processes are performed to achieve the different thicknesses H1, H2, H3, H4, H5, and H6 for the top dielectric layers 320A and 320B.

In other embodiments, due to the different sizes of spacings S4, S5, and S6 between the active regions 304B1 to 304B6 discussed above, a loading effect is induced. The loading effect can facilitate a selective growth process to achieve different thicknesses H4, H5, and H6 for the top dielectric layers 320B. More specifically, the formation of the top dielectric layers 320B1, 320B3, 320B5, and 320B7 to be formed in the larger spacings S5 and S6 is controlled to be formed at a higher formation rate, and the formation of top dielectric layers 320B2, 320B4, and 320B6 to be formed in the smaller spacings S4 is controlled to be formed at a lower formation rate. Therefore, the thicknesses H5 and H6 are greater than the thickness H4, and the top dielectric layers 320B with the different thicknesses H4, H5, and H6 are achieved. Moreover, since the spacing S5 is larger than the spacing S2 and the spacing S6 is larger than the spacing S3, the thickness H2 smaller than the thickness H5 and the thickness H3 smaller than the thickness H6 are also achieved.

Referring to FIGS. 10A to 10D, dummy gate structures 412-1 to 412-5 (may be collectively referred to as the dummy gate structures 412) are formed over the fins 410A and 410B. The dummy gate structures 412 may extend in the Y-direction, as shown in FIGS. 10A and 10B. In some embodiments, in order to form the dummy gate structures 412, a dummy dielectric material for dummy dielectric layers 414 is first formed over fins 410A and 410B and the top dielectric layers 320A and 320B. In some embodiments, the dummy dielectric layers 414 may include a dielectric material such as a nitride (e.g., Si₃N₄, SiON), a carbide (e.g., silicon carbide (SiC)), an oxide (e.g., SiO₂), or some other suitable materials. Then, in some embodiments, a dummy gate material for dummy gate electrodes 416 is formed over the dummy dielectric material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or a combination thereof. The dummy gate material and/or the dummy dielectric material may be formed by way of a thermal oxidation process and/or a deposition process (e.g., physical vapor deposition (PVD), CVD, PECVD, and ALD).

Afterward, one or more etching processes may be performed to pattern the dummy gate material for the dummy gate electrodes 416 and the dummy dielectric material for the dummy dielectric layers 414, thereby forming the dummy gate structures 412 each having the dummy dielectric layer 414 and the dummy gate electrode 416. The dummy gate structures 412 may undergo a gate replacement process through subsequent processing to form metal gates, such as a high-k metal gate, as discussed in greater detail below.

Still referring to FIGS. 10A to 10D, after the formation of the dummy gate structures 412, the gate spacers 324 discussed above are formed on sidewalls of the dummy gate structures 412 and over the top surfaces of the fins 410A and 410B. More specifically, the gate spacers 324 are formed on opposite sidewalls of the dummy gate structures 412 in the X-direction. The gate spacers 324 may include Si₃N₄, SiO₂, SiC, silicon oxycarbide (SiOC), SiON, silicon carbon nitride (SiCN), silicon oxycarbon nitride (SiOCN), carbon doped oxide, nitrogen doped oxide, porous oxide, or combinations thereof. In some embodiments, the gate spacers 324 include a low-k dielectric material, such as those described herein. The gate spacers 324 may include a single layer or a multi-layer structure.

In some embodiments, the gate spacers 324 may be formed by conformally depositing a spacer layer (containing the dielectric material) over the fins 410A and 410B and dummy gate structures 412. Then, an anisotropic etching process is performed to remove horizontal portions of the spacer layer from the top surfaces of the top dielectric layers 320A and 320B, the fins 410A and 410B, and the dummy gate structures 412. After the anisotropic etching process, the portions of the spacer layer formed on sidewall surfaces of the fins 410A and 410B and the dummy gate structures 412 substantially remain and become the gate spacers 324. In some embodiments, the anisotropic etching process is a dry (e.g., plasma) etching process. Additionally or alternatively, the formation of the gate spacers 324 may also involve chemical oxidation, thermal oxidation, CVD, PVD, ALD, HDPCVD, MOCVD, RPCVD, PECVD, LPCVD, ALCVD, APCVD, FCVD, and/or other suitable methods.

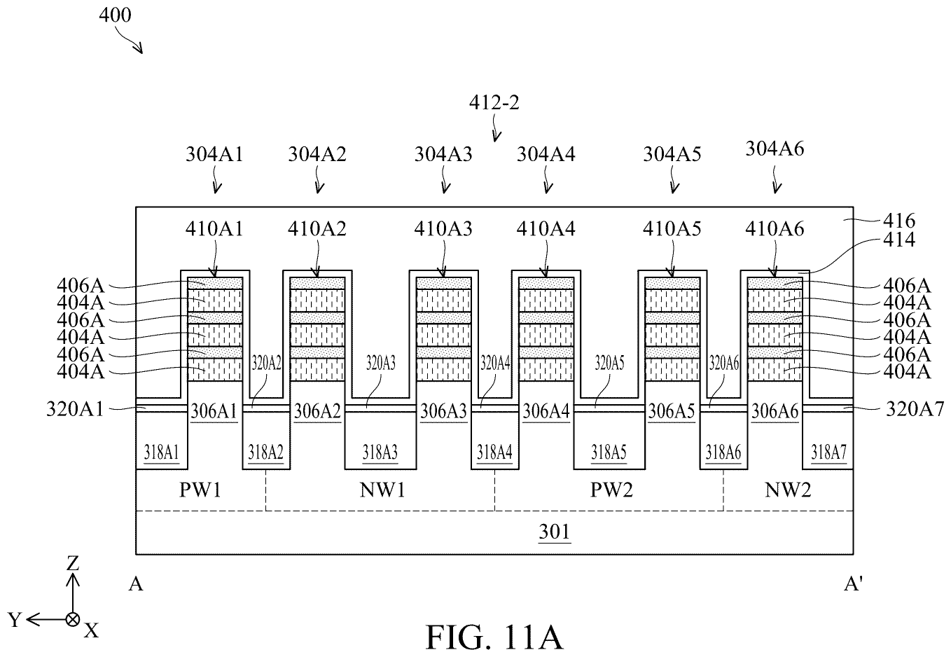

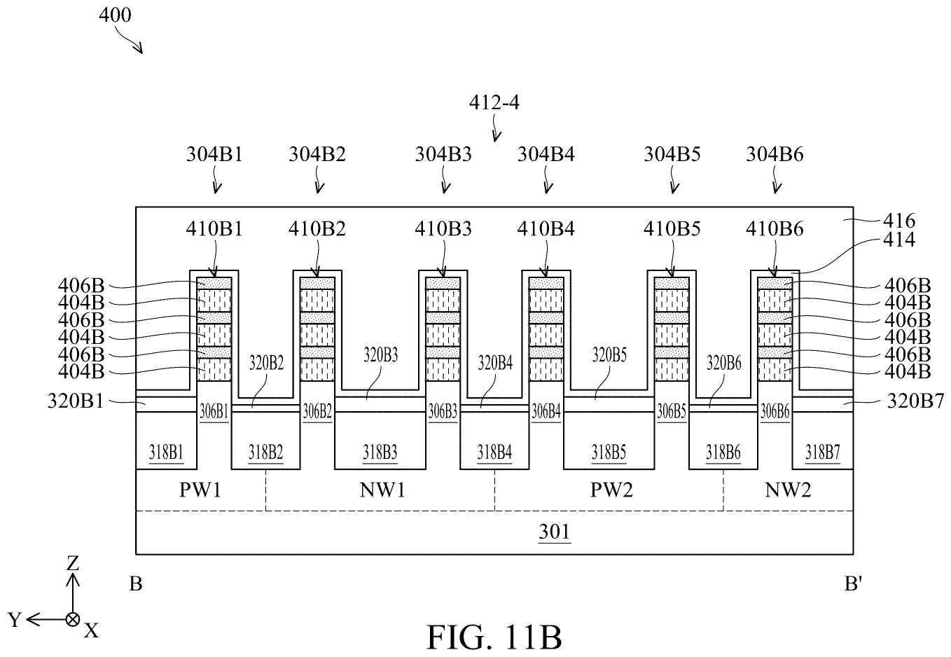

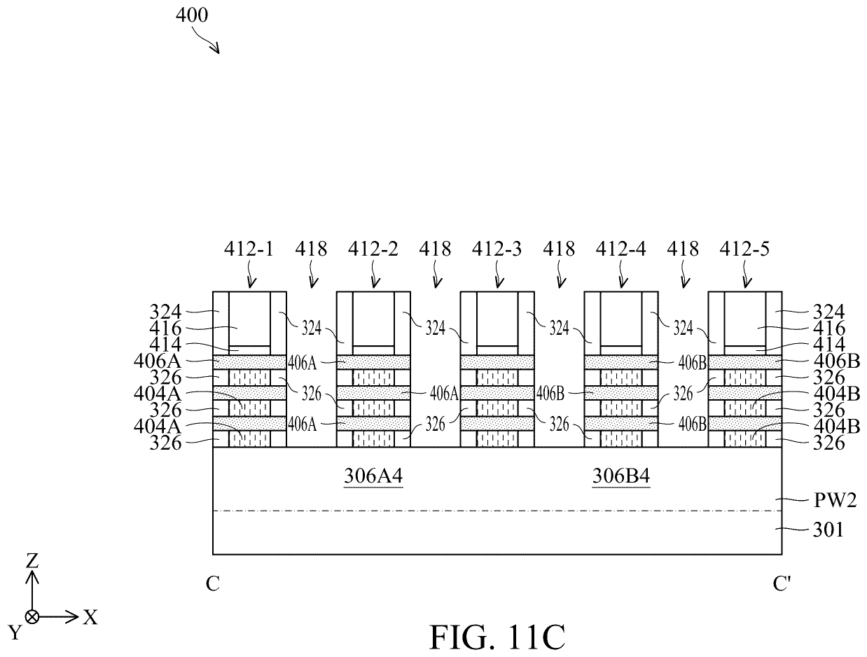

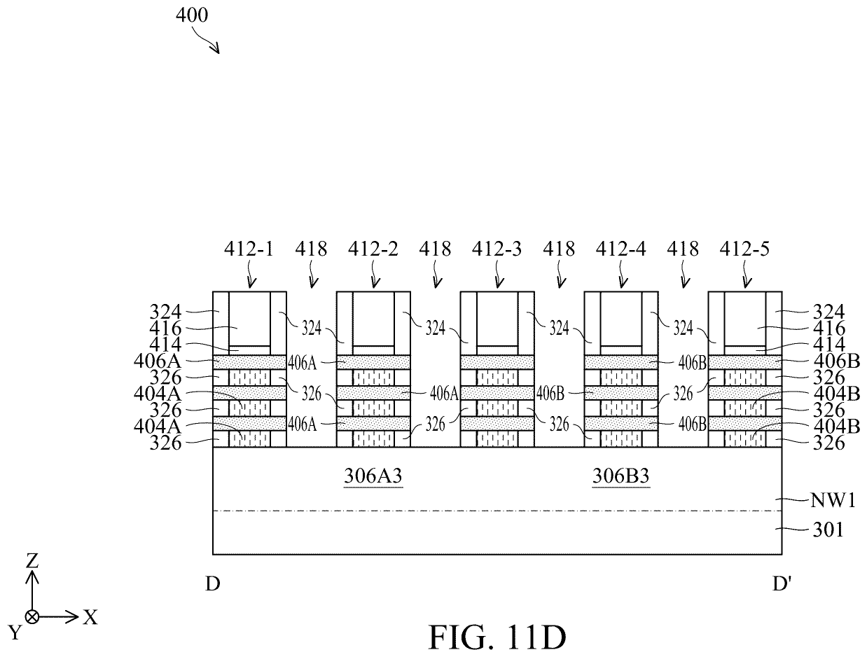

Referring to FIGS. 11A to 11D, the fins 410A and 410B are recessed to form source/drain trenches 418 in the fins 410A and 410B (or passing through the semiconductor layers 404A/404B and 406A/406B), in accordance with some embodiments. Specifically, the source/drain trenches 418 are formed on opposite sides of the dummy gate structures 412 in the X-direction. The source/drain trenches 418 may be formed by performing one or more etching processes to remove portions of the semiconductor layers 404A/404B and 406A/406B and the substrate 301 that the dummy gate structures 412 and the gate spacers 324 do not cover or vertically overlap. In some embodiments, a single etchant is used to remove the semiconductor layers 404A/404B and 406A/406B and the substrate 301. In other embodiments, multiple etchants are used to perform the etching process. In some embodiments, portions of the substrate 301 are etched, so that the source/drain trenches 418 extend into the substrate 301.

Still referring to FIGS. 11A to 11D, the inner spacers 326 discussed above are formed between the semiconductor layers 406A/406B as well as between the semiconductor layers 406A/406B and the substrate 301, in accordance with some embodiments. In some embodiments, the semiconductor layers 404A and 404B exposed in the source/drain trenches 418 are partially recessed through a selective etching process. Specifically, the selective etching process is performed that selectively etches the side portions of the semiconductor layers 404A and 404B below the gate spacers 324, with minimal etching (or substantially no etching) of the semiconductor layers 406A and 406B and the substrate 301. After the selective etching process, inner spacer recesses are vertically formed between the semiconductor layers 406A/406B as well as between the semiconductor layers 406A/406B and the substrate 301, below the gate spacers 324. The selective etching process may be a dry etching process, a wet etching process, other suitable etching process, or a combination thereof.

Next, in some embodiments, a spacer layer is conformally formed into the source/drain trenches 418 and the inner spacer recesses through a deposition process. The deposition process may include CVD, PVD, ALD, HDPCVD, MOCVD, RPCVD, PECVD, LPCVD, ALCVD, APCVD, FCVD, other suitable methods, or combinations thereof. The spacer layer partially (or completely) fills the source/drain trenches 418 and fully fills the inner spacer recesses. Furthermore, the spacer layer is also conformally formed on the gate spacers 324 and the top dielectric layers 320A and 320B.

The spacer layer may include a material that is different than the materials of the semiconductor layers 406A and 406B and the gate spacers 324 to achieve desired etching selectivity during the etching process. In some embodiments, the spacer layer includes a dielectric material such as Si₃N₄, SiO₂, SiC, SiOC, SiON, SiOCN, air gap, or a combination thereof. In some embodiments, the spacer layer includes a low-k dielectric material, such as those described herein.

Then, in some embodiments, an etching process is performed to selectively etch the spacer layer to form the inner spacers 326 with minimal etching (or substantially no etching) of the semiconductor layers 406A and 406B, the substrate 301, the dummy gate structures 412, and the gate spacers 324. The etching process may be an anisotropic etching process, removing the portions of the spacer layer that the dummy gate structures 412 and the gate spacers 324 do not cover or vertically overlap.

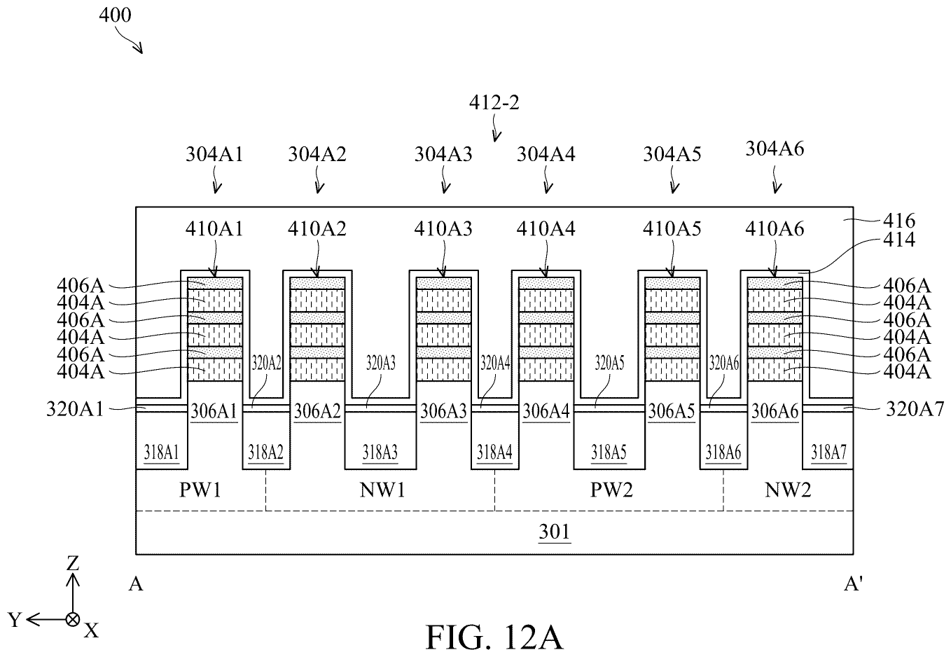

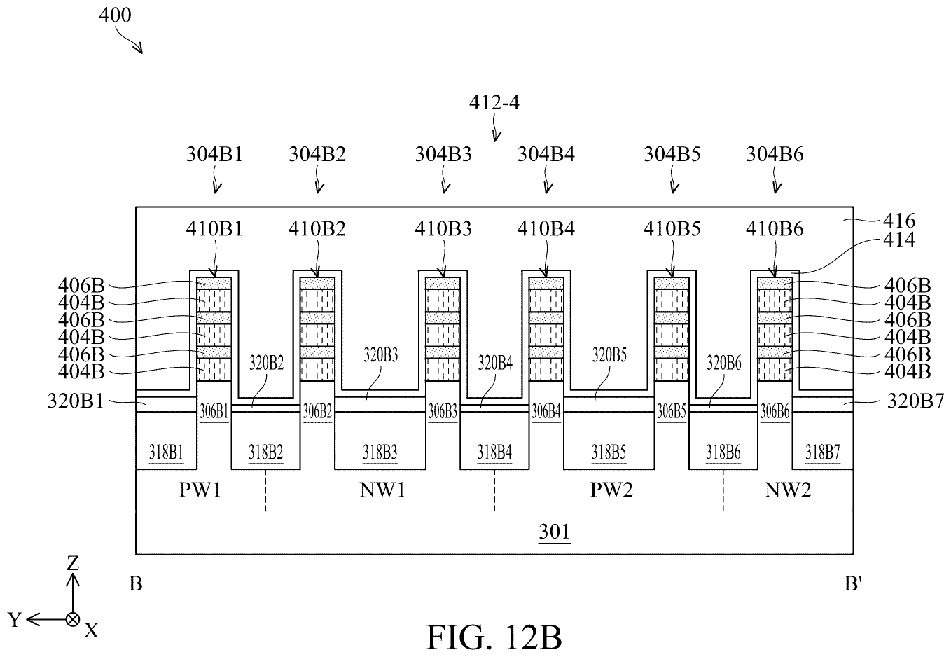

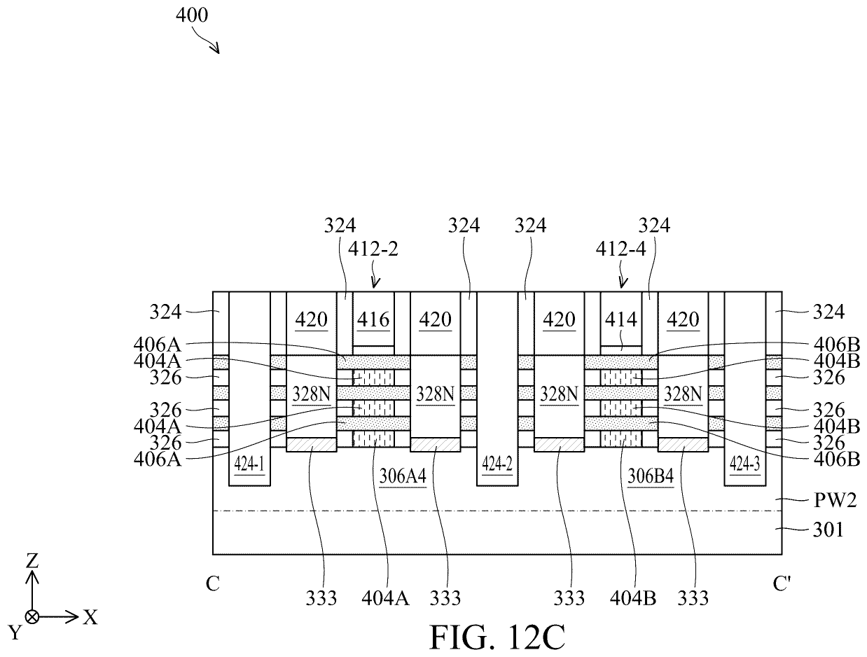

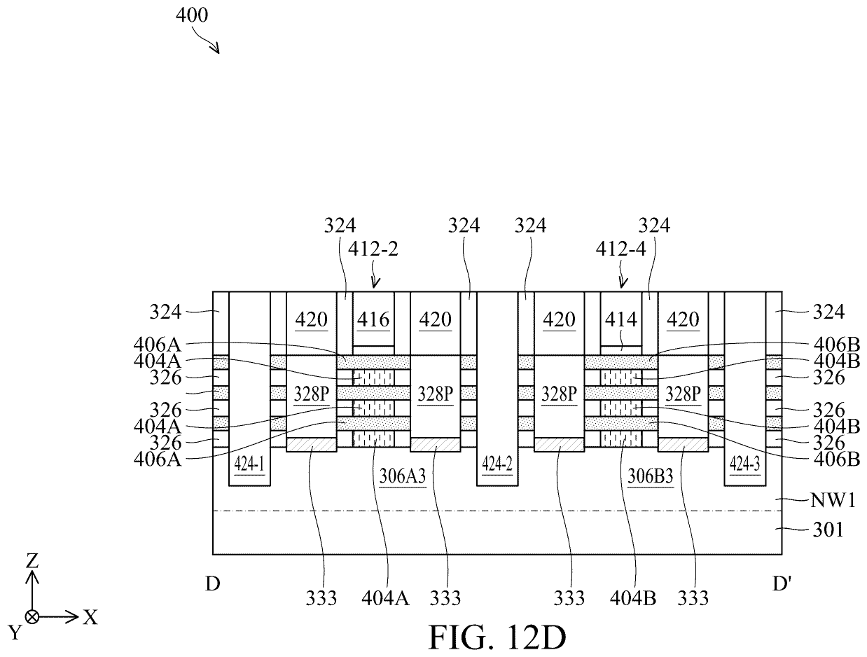

Referring to FIGS. 12A to 12D, the gate isolation structures 424-1, 424-2, and 424-3 (may be collectively referred to as gate isolation structures 424) are formed to replace portions of the dummy gate structures 412 and the semiconductor layers 404A, 404B, 406A, and 406B, in accordance with some embodiments. More specifically, the dummy gate structures 412-1, 412-3, and 412-5 and the semiconductor layers 404A, 404B, 406A, and 406B below the dummy gate structures 412-1, 412-3, and 412-5 are replaced with gate isolation structures 424-1, 424-2, and 424-3, respectively, as shown in FIGS. 12C and 12D. In order to form the gate isolation structures 424, one or more photolithography and etching processes may be performed to remove the portions of the dummy gate structures 412 (i.e., the dummy gate structures 412-1, 412-3, and 412-5) and the semiconductor layers 404A, 404B, 406A, and 406B in the regions to be formed the gate isolation structures 424. Then, the dielectric material are formed in the regions to be formed the gate isolation structures 424. As shown in FIGS. 12C and 12D, portions of the substrate 301 in the regions to be formed the gate isolation structures 424 are also removed. Therefore, the top surfaces of the substrate 301 in contact with the gate isolation structures 424 are lower than other the top surfaces of the substrate 301.

In some embodiments, the gate isolation structures 424 may be single dielectric layer or multiple layers and selected from a group consisting of SiO₂, SiOC, SiON, SiOCN, carbon content oxide, nitrogen content oxide, carbon and nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or combinations thereof.

Still referring to FIGS. 12A to 12D, the bottom isolation layers 333 discussed above are formed in lower parts of the source/drain trenches 418, in accordance with some embodiments. In some embodiments, the bottom isolation layers 333 are formed on the bottoms of the source/drain trenches 418, such that the bottom isolation layers 333 extend into and are in direct contact with the substrate 301 in the Z-direction. In some embodiments, the top surfaces of the bottom isolation layers 333 are lower than the bottom surfaces of the bottommost semiconductor layers 406A/406B. In some embodiments, the top surfaces of the bottom isolation layers 333 are above the topmost surfaces of the substrate 301. In some embodiments, the bottom isolation layers 333 may be a single layer or a multi-layer structure. In some embodiments, the dielectric material of the bottom isolation layers 333 may include Si₃N₄, SiO₂, SiC, SiOC, SiON, SiCN, SiOCN, high-k dielectrics, other suitable materials, or combinations thereof. In some embodiments, the bottom isolation layers 333 may be deposited by CVD, PVD, ALD, HDPCVD, MOCVD, RPCVD, PECVD, LPCVD, ALCVD, APCVD, other suitable methods, or combinations thereof.

Still referring to FIGS. 12A to 12D, the source/drain features 328N and 328P discussed above are formed in the source/drain trenches 418 and over the bottom isolation layers 333, in accordance with some embodiments. The source/drain features 328N/328P are also formed on opposite sides of the dummy gate structures 412 in the X-direction, as shown in FIGS. 12C and 12D. In some embodiments, the source/drain features 328N and 328P are formed using an epitaxial growth process. The epitaxial growth process may include VPE, MOCVD, MBE, or other deposition processes, such as CVD, LPCVD, PECVD, ALD, UHVCVD, RPCVD, combinations thereof, or the like. The source/drain features 328N and 328P may be doped in-situ or ex-situ. In some embodiments, one or more annealing processes may be performed to activate the dopants in the source/drain features 328N and 328P. The annealing processes may include rapid thermal annealing (RTA) and/or laser annealing processes.

Still referring to FIGS. 12A to 12D, after the formation of the source/drain features 328N and 328P, ILD layers 420 are formed to fill the space between the gate spacers 324, in accordance with some embodiments. The ILD layers 420 may include TEOS formed oxide, un-doped silicate glass, or doped silicon oxide such as BPSG FSG, PSG, BSG, a low-k dielectric material, another suitable dielectric material, or a combination thereof. The ILD layers 420 may be formed by CVD, PVD, ALD, HDPCVD, MOCVD, RPCVD, PECVD, LPCVD, ALCVD, APCVD, FCVD, or other suitable methods.

In some embodiments, before the formation of the ILD layers 420, contact etch stop layers (CESLs) may be conformally formed on the sidewalls of the gate spacers 324 and over the surfaces of the source/drain features 328N and 328P. The ILD layers 420 are then formed over and between the CESLs to fill the space between the CESLs. The CESLs includes a material that is different than the ILD layers 420. The CESLs may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, SiN, Y₂O₃, AlON, TaCN, ZrSi, or other suitable materials. The CESLs may be formed by CVD, PVD, ALD, HDPCVD, MOCVD, RPCVD, PECVD, LPCVD, ALCVD, APCVD, FCVD, or other suitable methods.

Subsequent to the deposition of the CESLs (if present) and the ILD layers 420, a CMP process and/or some other planarization process is performed on the CESLs, the ILD layers 420, and the gate spacers 324 until the top surfaces of the dummy gate electrodes 416 are exposed. In some embodiments, portions of the dummy gate electrodes 416 are removed after the planarization process.

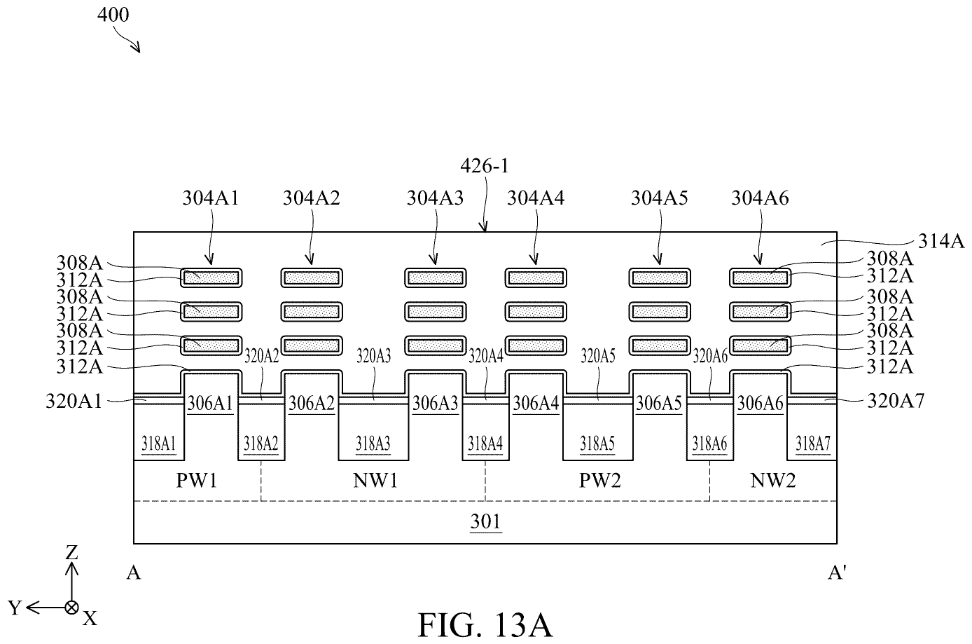

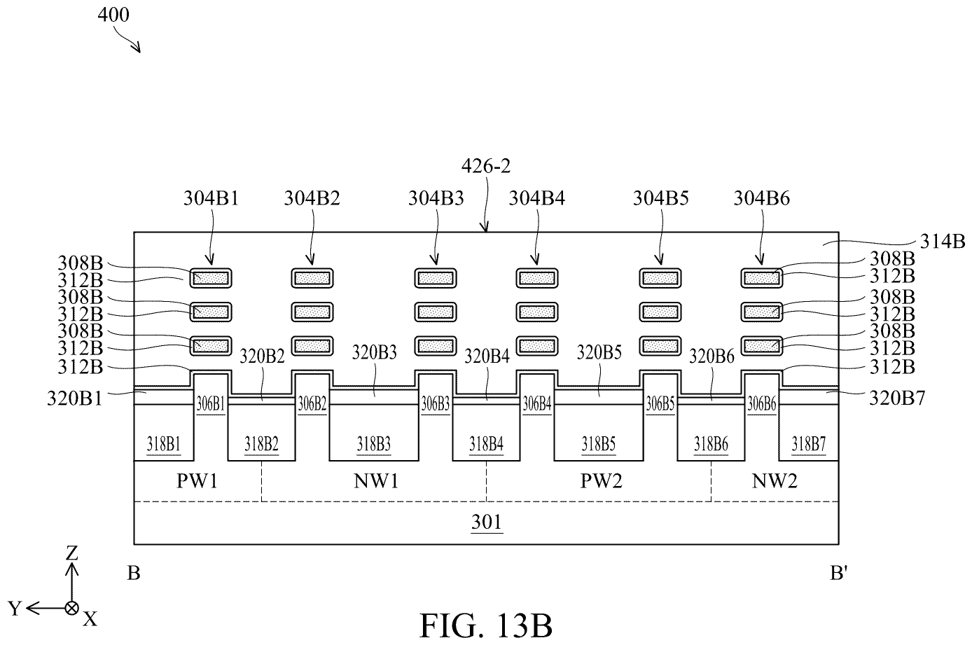

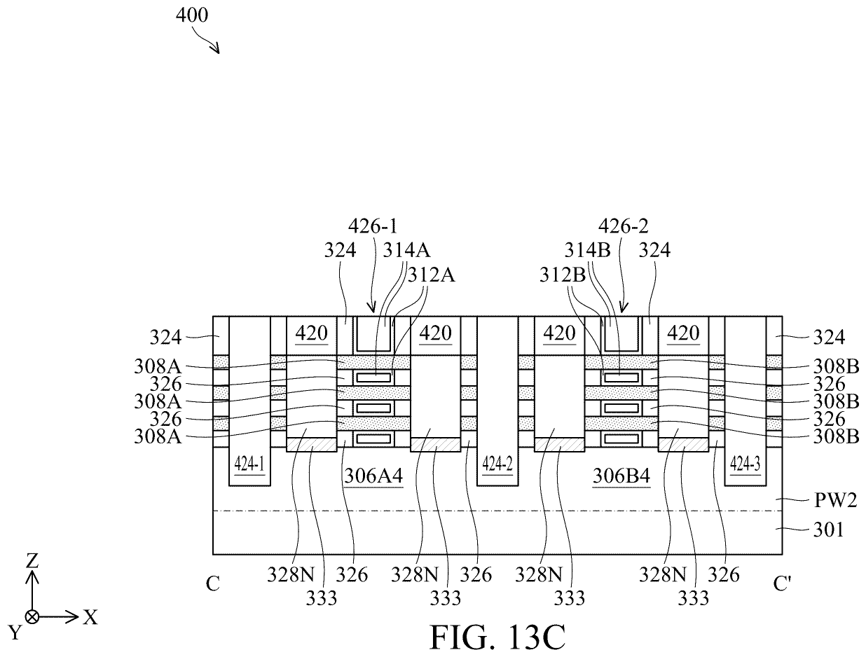

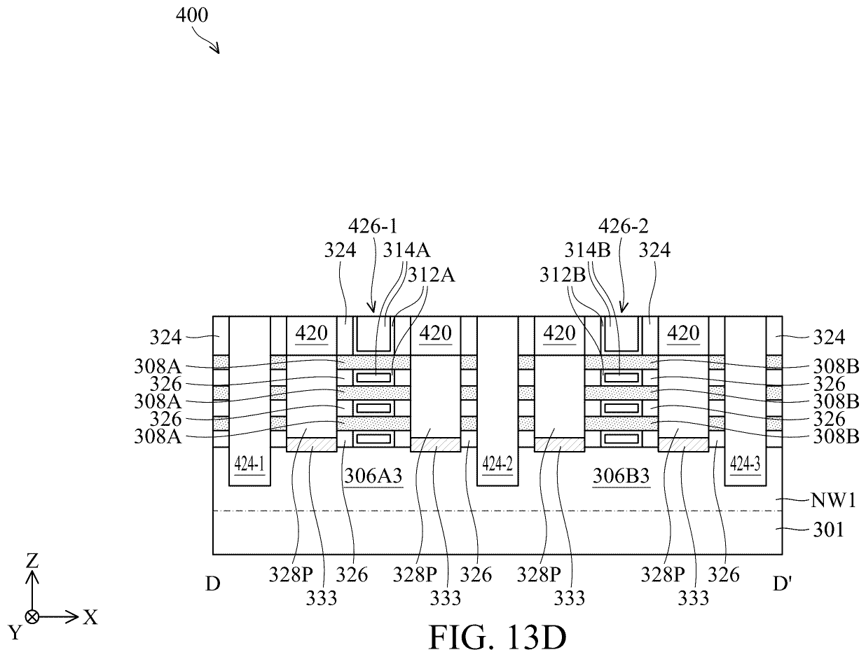

Referring to FIGS. 13A to 13D, the dummy gate structures 412-2 and 412-4 are selectively removed through any suitable photolithography and etching processes, in accordance with some embodiments. In some embodiments, the photolithography process may include forming a masking element, which exposes a region including the dummy gate structures 412-2 and 412-4. Then, the dummy gate structures 412-2 and 412-4 are selectively etched through the masking element. Etch selectivity may be achieved by selecting the appropriate etching chemicals, and the dummy gate structures 412-2 and 412-4 may be removed without substantially affecting the gate spacers 324, the inner spacers 326, and the substrate 301. The removal of the dummy gate structures 412-2 and 412-4 creates gate trenches. The gate trenches expose the top surfaces of the topmost semiconductor layers 406A/406B underlies the dummy gate structures 412-2 and 412-4.

Then, in some embodiments, the semiconductor layers 404A and 404B in the fins 410 are selectively removed through the gate trenches, using a wet etching process or dry etching process for example, so that the semiconductor layers 406A and 406B in the fins 410 are exposed in the gate trenches to form the nanostructures 308A and 308B discussed above. Such a process may also be referred to as a wire/sheet/channel release process, or a wire/sheet/channel formation process. As described above, the top dielectric layers 320 including the nitrogen content material can protect the isolation structures 318 and the top dielectric layers 320 during the channel release process. Therefore, the heights of the isolation structures 318 and the top dielectric layers 320 can be maintained after such a process. In some embodiments, since the widths of the semiconductor layers 404B is less than the widths of the semiconductor layers 404A, the semiconductor layers 406B will be etched more than the semiconductor layers 406A. Therefore, the thicknesses of the nanostructures 308A formed from the semiconductor layers 406A is greater than the thicknesses of the nanostructures 308B formed from the semiconductor layers 406B by at least 5% in the Z-direction.

Still referring to FIGS. 13A to 13D, a gate structure 426-1 is formed in the gate trench formed from the dummy gate structure 412-2 to wrap around the semiconductor layers 406A (the nanostructures 308A), and a gate structure 426-2 is formed in the gate trench formed from the dummy gate structure 412-4 to wrap around the semiconductor layers 406B (the nanostructures 308B), in accordance with some embodiments. Similar to the gate structures 310A and 310B discussed above, the gate structure 426-1 includes the gate dielectric layers 312A and the gate electrode layer 314A, and the gate structure 426-2 includes the gate dielectric layers 312B and the gate electrode layer 314B.

In some embodiments, the gate dielectric layers 312A are formed to wrap around the nanostructures 308A in the gate trench formed from the dummy gate structure 412-2, and the gate dielectric layers 312B are formed to wrap around the nanostructures 308B in the gate trench formed from the dummy gate structure 412-4. In some embodiments, the gate dielectric layers 312A are also formed on the sidewalls of the inner spacers 326 and the gate spacers 324, and over the top surfaces of the top dielectric layers 320A and the base fins 306A. Similarly, the gate dielectric layers 312B are also formed on the sidewalls of the inner spacers 326 and the gate spacers 324, and over the top surfaces of the top dielectric layers 320B and the base fins 306B.

In some embodiments, the gate dielectric layers 312A and 312B may include a dielectric material, such as SiOCN, SiOC, SiCN, SiO₂, SiN, SiC, or other suitable materials. In some embodiments, the gate dielectric layers 312A and 312B include a high-k dielectric material that has a dielectric constant greater than a dielectric constant of SiO₂, which is approximately 3.9. For example, the gate dielectric layers 312A and 312B may include hafnium oxide (HfO₂), which has a dielectric constant that is in a range from about 18 to about 40. Alternatively, the gate dielectric layers 312A and 312B may include other high-k dielectrics, such as TiO₂, HfZrO, Ta₂O₃, HfSiO4, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, SiN, SiON, a combination thereof, or another suitable material. The gate dielectric layers 312A and 312B may be formed by CVD, PVD, ALD, HDPCVD, MOCVD, RPCVD, PECVD, LPCVD, ALCVD, APCVD, FCVD, oxidation, and/or other suitable methods.

In some embodiments, the gate structures 426-1 and 426-2 may further include an interfacial layer (not shown) that is formed to wrap around the exposed nanostructures 308A and 308B before forming the gate dielectric layers 312A and 312B, so that the gate dielectric layers 312A and 312B are separated from the nanostructures 308A and 308B by the interfacial layers. In some embodiments, the interfacial layer may include a dielectric material such as SiO₂, HfSiO, or SiON. The interfacial layer may be formed by chemical oxidation, thermal oxidation, CVD, PVD, ALD, HDPCVD, MOCVD, RPCVD, PECVD, LPCVD, ALCVD, APCVD, FCVD, and/or other suitable method.

In some embodiments, the gate electrode layer 314A is then formed to fill the remaining spaces of the gate trench formed from the dummy gate structure 412-2, and over the gate dielectric layers 312A in such a way that the gate electrode layer 314A wraps around the gate dielectric layer 312A, the interfacial layers (if present), and the nanostructures 308A. In some embodiments, the gate electrode layer 314B is then formed to fill the remaining spaces of the gate trench formed from the dummy gate structure 412-4, and over the gate dielectric layers 312B in such a way that the gate electrode layer 314B wraps around the gate dielectric layer 312B, the interfacial layers (if present), and the nanostructures 308B.

The gate electrode layers 314A and 314B may include a single layer or a multi-layer structure. In some embodiments, the gate electrode layers 314A and 314B may include a capping layer, a barrier layer, work function metal layers, and/or a fill material. The gate electrode layers 314A and 314B may be formed using a deposition process such as CVD, PVD, ALD, HDPCVD, MOCVD, RPCVD, PECVD, LPCVD, ALCVD, APCVD, FCVD, or the like, although any suitable deposition process may be used.

In some embodiments, the capping layer and the barrier layer may include different materials, and may be formed of metallic materials such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

For p-type GAA transistors, the gate electrode layer may include p-type work function metal layers. For n-type GAA transistors, the gate electrode layer may include n-type work function metal layers. The n-type and p-type work function metal layers may include conductive materials tuned to have a desired work function (e.g., an n-type work function or a p-type work function). In some embodiments, the n-type and p-type work function metal layers may include a material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the fill material may include a suitable conductive material, such as Al, W, and/or Cu.

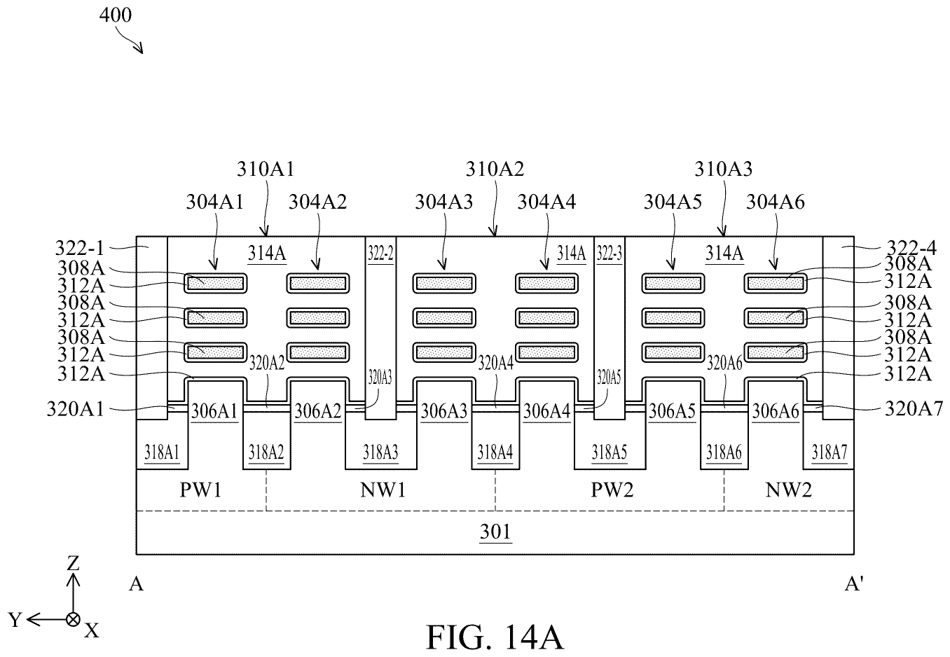

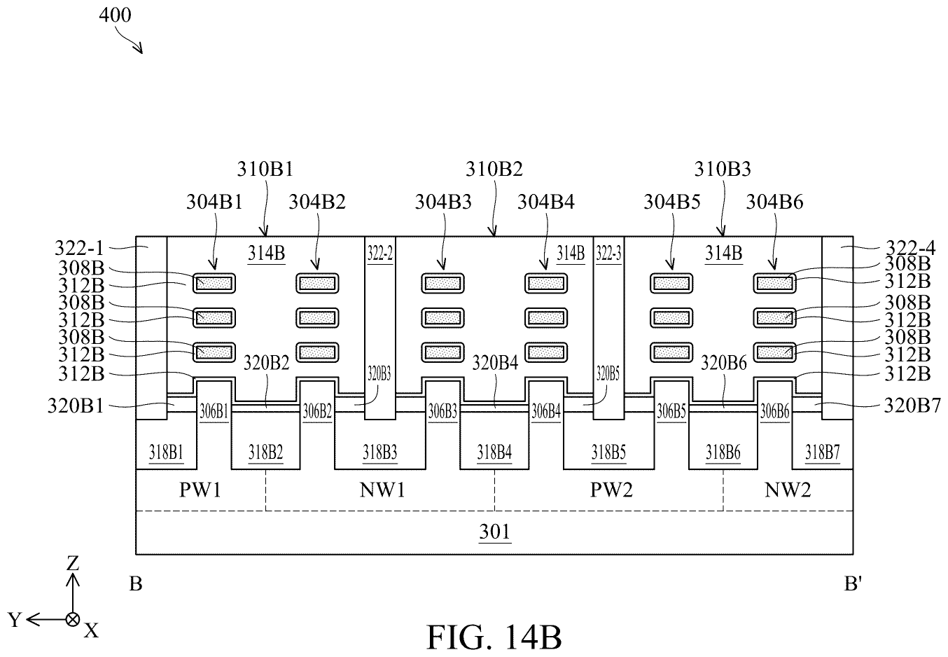

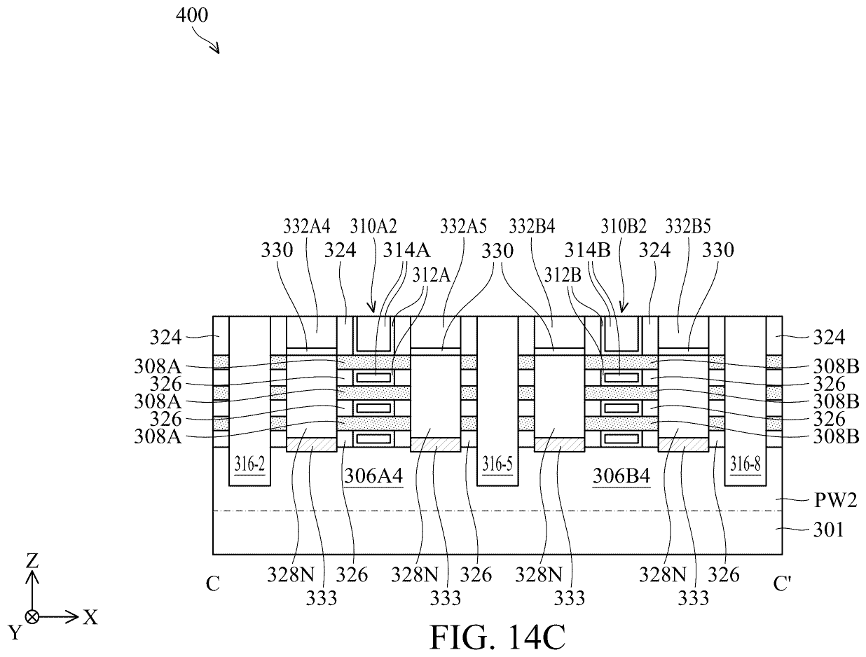

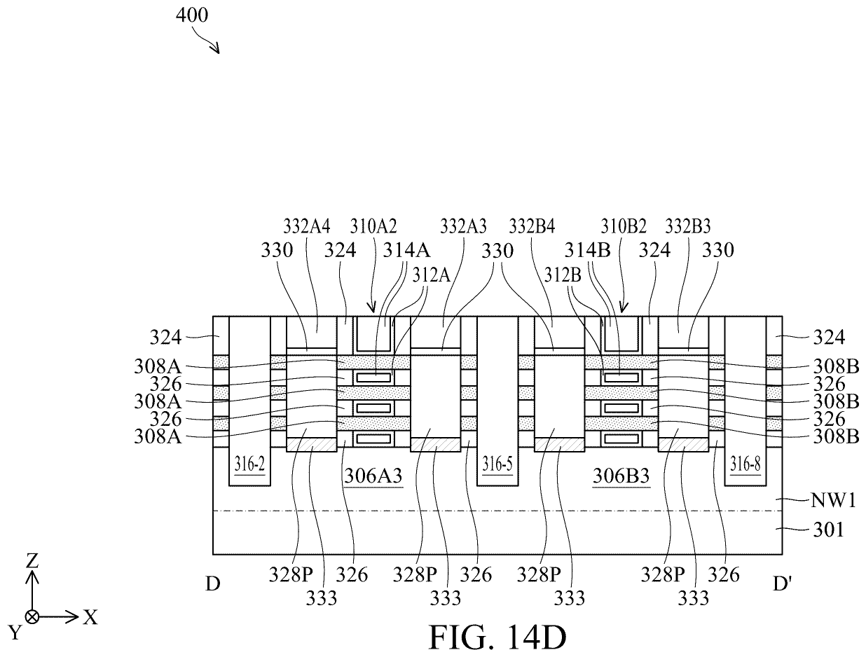

Referring to FIGS. 14A to 14D, the gate-end dielectric structures 322 discussed above are formed, in accordance with some embodiments. In some embodiments, the gate-end dielectric structures 322-1 to 322-4 are formed in the gate structures 426-1 and 426-2, so as to cut the gate structure 426-1 into the gate structures 310A1, 310A2, and 310A3 discussed above, and cut the gate structure 426-2 into the gate structures 310B1, 310B2, and 310B3 discussed above. In some embodiments, the gate-end dielectric structures 322-1 to 322-4 also cut the gate isolation structure 424-1 into the gate isolation structures 316-1, 316-2, and 316-3, cut the gate isolation structure 424-2 into the gate isolation structures 316-4, 316-5, and 316-6, and cut the gate isolation structure 424-3 into the gate isolation structures 316-7, 316-8, and 316-9. As such, gate-end dielectric structures 322 are disposed on the opposite sides of the gate structures 310A and 310B and on the opposite sides of the gate isolation structures 316 in the Y-direction. The gate-end dielectric structures 322 also separate the gate structures 310A and 310B and/or the gate isolation structures 316 from gate structures and/or gate isolation structures of other circuit cells (not shown) in other rows of the semiconductor device 300. In some embodiments, the gate-end dielectric structures 322 extend vertically into the isolation structures 318. More specifically, as shown in FIGS. 14A and 14B, the gate-end dielectric structures 322 pass through the top dielectric layers 320 and extend vertically into the isolation structures 318.

The formation of the gate-end dielectric structures 322 may include forming trenches extending through the gate structures 426-1 and 426-2, the gate isolation structures 424, and the top dielectric layers 320 and partially extending into the isolation structures 318. Then, a dielectric material is deposited into the trenches. In some embodiments, since the gate-end dielectric structures 322 are formed after the gate structures 426-1 and 426-2, the gate-end dielectric structures 322 pass through the gate dielectric layers 312A and 312B formed on the top dielectric layers 320, as shown in FIGS. 14A and 14B.

The dielectric material of the gate-end dielectric structures 322 may include SiN, SiO₂, SiC, SiON, SiOC, SiCN, SiOCN, ZrSiO₂, HfO₂, HfSiO₄, LaO, Al₂O₃, combinations thereof, or the like, although any suitable material may be used. The gate-end dielectric structures 322 may include a single layer or a multi-layer structure. In some embodiments, the gate-end dielectric structures 322 may include a first dielectric layer made of silicon nitride, and a second dielectric layer made of silicon oxide and formed on the first dielectric layer. In some embodiments, the material of the gate-end dielectric structures 322 is different from the material of the gate spacers 324. The gate-end dielectric structures 322 may be formed using a deposition process such as CVD, PVD, ALD, HDPCVD, MOCVD, RPCVD, PECVD, LPCVD, ALCVD, APCVD, FCVD, other suitable methods, or combinations thereof.

Still referring to FIGS. 14A to 14D, the silicide layers 330 and source/drain contacts 332A and 332B discussed above are formed over the source/drain features 328N/328P. The silicide layers 330 and source/drain contacts 332A and 332B are also formed in the ILD layers 420. The formation of the source/drain contacts 332A and 332B may include forming contact openings passing through the ILD layers 420 and exposing the source/drain features 328N and 328P, forming the silicide layers 330 on the exposed surface of the source/drain features 328N and 328P, and depositing a conductive material in the contact openings to form the source/drain contacts 332A and 332B. In some embodiments, the silicide layers 330 are formed by depositing metal layers on the source/drain features 328N and 328P, and heating the workpiece 400 to cause constituents of the source/drain features 328N and 328P to react with metal constituents of the metal layers. The conductive material of the source/drain contacts 332A and 332B may include Al, Cu, W, Co, Ti, Ta, Ru, Rh, Ir, Pt, TiN, TiAl, TiAlN, TaN, TaC, combinations thereof, or the like, although any suitable material may be used. The source/drain contacts 332A and 332B may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. However, any suitable materials and processes may be utilized to form source/drain contacts 332A and 332B. In some embodiments, the source/drain contacts 332A and 332B may each include single conductive material layer or multiple conductive layers.

After the formation of the source/drain contacts 332A and 332B, the cap layer 334, the ILD layer 336, the IMD layer 338, the vias VD, and the gate vias VG are formed over the source/drain contacts 332A and 332B, in accordance with some embodiments. As such, the semiconductor device 300 as shown in FIGS. 3 and 4A to 4B discussed above has been formed.

The embodiments disclosed herein relate to semiconductor structures and their forming methods, and more particularly to methods and semiconductor structures that include different active region spacings and different top dielectric layer (formed on isolation structure) thicknesses for circuit cells. Furthermore, the present embodiments provide one or more of the following advantages. The active region spacing in one circuit cell is smaller for reducing the dimension of the gate structure in the longitudinal direction, which reduces the gate-to-contact parasitic capacitance. The active region spacing between different circuit cells is larger to create loading effect, which can induce the different top dielectric layer thicknesses. The smaller top dielectric layer thickness between the active regions in one circuit cell has larger process window in channel release process. The larger top dielectric layer thickness between the active regions in different circuit cells prevent the contact area between the gate structures and the base fins from increasing during the channel release process, so as to avoid the increase of the parasitic capacitance. As a result, the process margin and the device performance are improved.

In one exemplary aspect, the present disclosure is directed to a semiconductor device. The semiconductor device includes a first active region including a first base fin, a second active region including a second base fin and spaced apart from the first active region in a first direction, a third active region including a third base fin, and a fourth active region including a fourth base fin and spaced apart from the third active region in the first direction. The semiconductor device further includes a fifth active region including a fifth base fin and spaced apart from the first active region in a second direction, a sixth active region including a sixth base fin and spaced apart from the second active region in the second direction, a seventh active region including a seventh base fin and spaced apart from the third active region in the second direction, and an eighth active region including an eighth base fin and spaced apart from the fourth active region in the second direction. The semiconductor device further includes isolation structures, disposed between the first base fin and the second base fin, between the second base fin and the third base fin, between the third base fin and the fourth base fin, between the fifth base fin and the sixth base fin, between the sixth base fin and the seventh base fin, and between the seventh base fin and the eighth base fin. The isolation structures include an oxide-based material. The semiconductor device further includes a first top dielectric layer formed on the isolation structures and between the sixth base fin and the seventh base fin, and a second top dielectric layer formed on the isolation structures and between the seventh base fin and the eighth base fin. The first thickness of the first top dielectric layer is greater than the second thickness of the second top dielectric layer.

In another exemplary aspect, the present disclosure is directed to a semiconductor device. The semiconductor device includes first, second, third, and fourth active regions. The first active region is formed in a first well region in a substrate and includes a first base fin. The second active region is formed in a second well region in the substrate, includes a second base fin, and is spaced apart from the first active region in a first direction. The third active region is formed in the second well region, includes a third base fin, and is spaced apart from the second active region in the first direction. The fourth active region is formed in a third well region in the substrate, includes a fourth base fin, and is spaced apart from the third active region in the first direction. The first well region and the third well region have a first conductivity type and the second well region has a second conductivity type. The semiconductor device further includes a first isolation structure and a first top dielectric layer on the first isolation structure, formed between the first base fin and the second base fin; and a second isolation structure and a second top dielectric layer on the second isolation structure, formed between the second base fin and the third base fin. The semiconductor device further includes a first gate structure formed on the first active region and the second active region, and a second gate structure formed on the third active region and the fourth active region, and a gate-end dielectric structure extending in the second direction and spacing apart the first gate structure from the second gate structure in the first direction. The first gate structure and the second gate structure extend along the first direction. The first, second, third, and fourth active regions extend along a second direction perpendicular to the first direction. The gate-end dielectric structure extends through the second top dielectric layer and extends into the second isolation structure, so that a bottom surface of the gate-end dielectric structure is lower than bottom surfaces of the first gate structure and the second gate structure. The first height between a top surface of the first top dielectric layer and a top surface of the second base fin is greater than the second height between a top surface of the second top dielectric layer and the top surface of the second base fin.

In yet another exemplary aspect, the present disclosure is directed to a method of forming a semiconductor device. The method includes forming a stack over a substrate, wherein the stack includes first semiconductor layers and second semiconductor layers that are stacked in an alternating manner. The method further includes patterning the stack and the substrate in a first region, so as to form a first active region including a first base fin, a second active region including a second base fin, a third active region including a third base fin, and a fourth active region including a fourth base fin. In a first direction, the first active region and the third active region are spaced apart from the second active region and the fourth active region, respectively. The method further includes patterning the stack and the substrate in a second region, so as to form a fifth active region including a fifth base fin, a sixth active region including a sixth base fin, a seventh active region including a seventh base fin, and an eighth active region including an eighth base fin. In a second direction different than the first direction, the fifth active region, the sixth active region, the seventh active region, and the eight active region are spaced apart from the first active region, the second active region, the third active region, and the fourth active region, respectively. The method further includes forming isolation structures between the first active region, the second active region, the third active region, and the fourth active regions and between the fifth active region, the sixth active region, the seventh active region, and the eight active region. The method further includes forming a first top dielectric layer on the isolation structures and between the sixth base fin and the seventh base fin; and forming a second top dielectric layer on the isolation structures and between the seventh base fin and the eighth base fin. The first thickness of the first top dielectric layer is greater than the second thickness of the second top dielectric layer.

In yet another exemplary aspect, the present disclosure is directed to a semiconductor device. The semiconductor device includes a first gate-end dielectric structure and a second gate-end dielectric structure, extending in a first direction and spaced apart from each other in a second direction that is perpendicular to the first direction. The semiconductor device further includes a first circuit cell and a second circuit cell, arranged in the first direction and disposed between the first gate-end dielectric structure and the second gate-end dielectric structure. The first circuit cell includes a first active region extending in the first direction, a second active region extending in the first direction and disposed between the first active region and the second gate-end dielectric structure, and a first gate structure extending in the second direction and engaging the first active region and the second active region. The first circuit cell further includes a first isolation structure and a first top dielectric layer on the first isolation structure, disposed between the first active region and the second active region; and a second isolation structure and a second top dielectric layer on the second isolation structure, disposed below the second gate-end dielectric structure. The second circuit cell includes a third active region extending in the first direction, a fourth active region extending in the first direction and disposed between the third active region and the second gate-end dielectric structure, and a second gate structure extending in the second direction and engaging the third active region and the fourth active region. The second circuit cell further includes a third isolation structure and a third top dielectric layer on the third isolation structure, disposed between the third active region and the fourth active region; and a fourth isolation structure and a fourth top dielectric layer on the fourth isolation structure, disposed below the second gate-end dielectric structure. The first portion and the second portion of the second gate-end dielectric structure extend into the second isolation structure and the fourth isolation structure, respectively. The fourth thickness of the fourth top dielectric layer is greater than the first thickness of the first top dielectric layer, the second thickness of the second top dielectric layer, and the third thickness of the third top dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first active region, including a first base fin;
a second active region, including a second base fin and spaced apart from the first active region in a first direction;
a third active region, including a third base fin;
a fourth active region, including a fourth base fin and spaced apart from the third active region in the first direction;
a fifth active region, including a fifth base fin and spaced apart from the first active region in a second direction;
a sixth active region, including a sixth base fin and spaced apart from the second active region in the second direction;
a seventh active region, including a seventh base fin and spaced apart from the third active region in the second direction;
an eighth active region, including an eighth base fin and spaced apart from the fourth active region in the second direction;
isolation structures, disposed between the first base fin and the second base fin, between the second base fin and the third base fin, between the third base fin and the fourth base fin, between the fifth base fin and the sixth base fin, between the sixth base fin and the seventh base fin, and between the seventh base fin and the eighth base fin, wherein the isolation structures comprise an oxide-based material;
a first top dielectric layer, formed on the isolation structures and between the sixth base fin and the seventh base fin; and
a second top dielectric layer, formed on the isolation structures and between the seventh base fin and the eighth base fin, wherein a first thickness of the first top dielectric layer is greater than a second thickness of the second top dielectric layer.

2. The semiconductor device of claim 1, further comprising:
a third top dielectric layer, formed on the isolation structures and between the second base fin and the third base fin; and
a fourth top dielectric layer, formed on the isolation structures and between the third base fin and the fourth base fin,
wherein the first thickness of the first top dielectric layer is greater than a third thickness of the third top dielectric layer and a fourth thickness of the fourth top dielectric layer.

3. The semiconductor device of claim 1, further comprising:
a first gate-end dielectric structure, extending in the second direction, spacing apart the second active region from the third active region and spacing apart the sixth active region from the seventh active region in the first direction, and extending through the first top dielectric layer, wherein a portion of the first gate-end dielectric structure extends into the isolation structures.

4. The semiconductor device of claim 1, wherein a first spacing between the sixth base fin and the seventh base fin is greater than a second spacing between the seventh base fin and the eighth base fin.

5. The semiconductor device of claim 4,
wherein the first spacing is greater than a third spacing between the second base fin and the third base fin, and
wherein the second spacing is substantially the same as a fourth spacing between the third base fin and the fourth base fin.

6. The semiconductor device of claim 1, further comprising:
a first gate structure, disposed on the first active region and the second active region;
a second gate structure, disposed on the fifth active region and the sixth active region; and
a gate isolation structure, disposed between and spacing apart the first gate structure and the second gate structure in the second direction.

7. The semiconductor device of claim 6,
wherein the first active region further comprises first nanostructures alternately stacked over the first base fin, the second active region further comprises second nanostructures alternately stacked over the second base fin, the fifth active region further comprises fifth nanostructures alternately stacked over the fifth base fin, and the sixth active region further comprises sixth nanostructures alternately stacked over the sixth base fin, and
wherein the first gate structure is wrapped around the first nanostructures and the second nanostructures, and the third gate structure is wrapped around the fifth nanostructures and the sixth nanostructures.

8. The semiconductor device of claim 7, wherein a first width of the first nanostructures is greater than a third width of the fifth nanostructures, and a second width of the second nanostructures is greater than a fourth width of the sixth nanostructures.

9. A semiconductor device, comprising:
a first active region, formed in a first well region in a substrate and including a first base fin;
a second active region, formed in a second well region in the substrate, including a second base fin, and spaced apart from the first active region in a first direction;
a third active region, formed in the second well region, including a third base fin, and spaced apart from the second active region in the first direction;
a fourth active region, formed in a third well region in the substrate, including a fourth base fin, and spaced apart from the third active region in the first direction, wherein the first well region and the third well region have a first conductivity type and the second well region has a second conductivity type;
a first isolation structure and a first top dielectric layer on the first isolation structure, formed between the first base fin and the second base fin;
a second isolation structure and a second top dielectric layer on the second isolation structure, formed between the second base fin and the third base fin;
a first gate structure, formed on the first active region and the second active region;
a second gate structure, formed on the third active region and the fourth active region, wherein the first gate structure and the second gate structure extend along the first direction, and wherein the first active region, the second active region, the third active region, and the fourth active region extend along a second direction perpendicular to the first direction; and
a gate-end dielectric structure, extending in the second direction and spacing apart the first gate structure from the second gate structure in the first direction, wherein the gate-end dielectric structure extends through the second top dielectric layer and extends into the second isolation structure, so that a bottom surface of the gate-end dielectric structure is lower than bottom surfaces of the first gate structure and the second gate structure,
wherein a first height between a top surface of the first top dielectric layer and a top surface of the second base fin is greater than a second height between a top surface of the second top dielectric layer and the top surface of the second base fin.

10. The semiconductor device of claim 9, further comprising:
a third isolation structure and a third top dielectric layer on the third isolation structure, formed between the third base fin and the fourth base fin,
wherein a third height between a top surface of the third base fin and a top surface of the third top dielectric layer is greater than the second height.

11. The semiconductor device of claim 9, further comprising:
a fifth active region, including a fifth base fin and spaced apart from the first active region in the second direction;
a sixth active region, including a sixth base fin and spaced apart from the second active region in the second direction; and
a fourth isolation structure and a fourth top dielectric layer on the fourth isolation structure, formed between the fifth base fin and the sixth base fin.

12. The semiconductor device of claim 11, wherein a fourth height between a top surface of the fifth base fin and a top surface of the fourth top dielectric layer is substantially the same as the first height.

13. The semiconductor device of claim 11,
wherein the first active region further comprises first nanostructures alternately stacked over the first base fin,
wherein the fifth active region further comprises fifth nanostructures alternately stacked over the fifth base fin, and
wherein a first width of the first nanostructures is smaller than a second width of the fifth nanostructures.

14. The semiconductor device of claim 11, further comprising:
a gate isolation structure, extending in the first direction,
wherein the gate isolation structure is disposed between the first active region and the fifth active region, and spaces apart the first active region from the fifth active region,
wherein the gate isolation structure is disposed between the second active region and the sixth active region, spaces apart the second active region from the sixth active region.

15. The semiconductor device of claim 11, wherein a first spacing between the first base fin and the second base fin is smaller than a second spacing between the second base fin and the third base fin.

16. The semiconductor device of claim 15, wherein a third spacing between the fifth base fin and the sixth base fin is substantially the same as the first spacing.

17. A method of forming a semiconductor device, comprising:
forming a stack over a substrate, wherein the stack comprises first semiconductor layers and second semiconductor layers that are stacked in an alternating manner;
patterning the stack and the substrate in a first region, so as to form a first active region including a first base fin, a second active region including a second base fin, a third active region including a third base fin, and a fourth active region including a fourth base fin, wherein in a first direction, the first active region and the third active region are spaced apart from the second active region and the fourth active region, respectively;
patterning the stack and the substrate in a second region, so as to form a fifth active region including a fifth base fin, a sixth active region including a sixth base fin, a seventh active region including a seventh base fin, and an eighth active region including an eighth base fin, wherein in a second direction different than the first direction, the fifth active region, the sixth active region, the seventh active region, and the eight active region are spaced apart from the first active region, the second active region, the third active region, and the fourth active region, respectively;
forming isolation structures between the first active region, the second active region, the third active region, and the fourth active regions and between the fifth active region, the sixth active region, the seventh active region, and the eight active region;
forming a first top dielectric layer on the isolation structures and between the sixth base fin and the seventh base fin; and
forming a second top dielectric layer on the isolation structures and between the seventh base fin and the eighth base fin, wherein a first thickness of the first top dielectric layer is greater than a second thickness of the second top dielectric layer.

18. The method of claim 17, further comprising:
forming a third top dielectric layer on the isolation structures and between the second base fin and the third base fin; and
forming a fourth top dielectric layer on the isolation structures and between the third base fin and the fourth base fin,
wherein the first thickness of the first top dielectric layer is greater than a third thickness of the third top dielectric layer and a fourth thickness of the fourth top dielectric layer.

19. The method of claim 17, further comprising:
removing the first semiconductor layers;
forming a first gate structure extending in the first direction, wherein the first gate structure is wrapped around the semiconductor layers in the first active region, the second active region, the third active region, and the fourth active region; and
forming a second gate structure extending in the first direction, wherein the second gate structure is wrapped around the semiconductor layers in the fifth active region, the sixth active region, the seventh active region, and the eighth active region.

20. The method of claim 19, further comprising:
forming a gate-end dielectric structure extending through the first gate structure and the third top dielectric layer to space apart the second active region from the third active region in the first direction, and extending through the second gate structure and the first top dielectric layer to space apart the sixth active region from the seventh active region in the first direction,
wherein a portion of the gate-end dielectric layer extends into the isolation structures.
